(19) United States
(12) Patent Application Publication
(10) Pub. No.: US 2012/0314109 A1
(43) Pub. Date: Dec. 13, 2012

(54) SOLID-STATE IMAGING DEVICE AND CAMERA

(75) Inventors: Masashi MURAKAMI, Kyoto (JP); Hirohisa Ohtsuki, Toyama (JP); Makota Ikuma, Kyoto (JP)

(73) Assignee: PANASONIC CORPORATION, Osaka (JP)

(21) Appl. No.: 13/592,943

(22) Filed: Aug. 23, 2012

Related U.S. Application Data
(63) Continuation of application No. PCT/JP2011/000964, filed on Feb. 22, 2011.

(30) Foreign Application Priority Data
Feb. 26, 2010 (JP) 2010-042494

(51) Int. Cl. H01L 27/146; H04N 5/335

(52) U.S. Cl. 348/300; 250/208.1; 348/E05.091

(57) ABSTRACT

The present invention implements a solid-state imaging device and a camera which develop lower noise. The solid-state imaging device includes unit cells which are arranged in two dimensions. Each of the unit cells includes: a photoelectric converting element which photoelectrically converts incident light; and amplifying transistors each of which outputs a signal voltage according to signal charges of the photoelectric converting element. The photoelectric converting element is electrically connected in common with gates of the amplifying transistors.

### CROSS REFERENCE TO RELATED APPLICATIONS

This is a continuation application of PCT Patent Application No. PCT/JP2011/000964 filed on Feb. 22, 2011, designating the United States of America, which is based on and claims priority of Japanese Patent Application No. 2010-042494 filed on Feb. 26, 2010. The entire disclosures of the above-identified applications, including the specifications, drawings and claims are incorporated herein by reference in their entirety.

### TECHNICAL FIELD

The present invention relates to solid-state imaging devices and cameras and, in particular, to a Metal Oxide Semiconductor (MOS) solid-state imaging device such as a Complementary MOS (CMOS) image sensor.

### BACKGROUND ART

A solid-state imaging device based on the CMOS technique is well known for its high performance, versatility, and low power consumption. Such a solid-state imaging device is also referred to as CMOS image sensor. Patent Literature 1 discloses a plan pattern view (layout) of a unit cell including four pixels (photoelectric converting elements).

### CITATION LIST

### Patent Literature

[PTL 1] Japanese Unexamined Patent Application Publication No. 2008-270299 (FIG. 3)

### SUMMARY OF INVENTION

### Technical Problem

As the size of a unit cell (cell size) becomes finer as a solid-state imaging device becomes smaller, the sensitivity of the unit cell deteriorates. In order to curb the deteriorating sensitivity due to the finer cell size, the area in the unit cell needs to be provided less for elements other than a photoelectric converting element. Such elements other than the photoelectric converting elements are an amplifying transistor and a reset transistor.

A smaller gate size of the amplifying transistor, however, increases thermal noise and 1/f noise which develop in the amplifying transistor. This leads to deterioration in random noise performance which develops in a unit cell.

Moreover, a narrower gate width of the amplifying transistor inevitably makes an output signal from the unit cell susceptible to noise of a bias supply provided to the gate of a constant current transistor. This leads to deterioration in random noise performance which horizontal-linearly appears. The cause of the horizontal linear noise is that the bias supply is commonly provided to gates of constant current transistors each of which is provided to a corresponding one of rows of the unit cells. Compared with point-like random noise developing in the unit cells, the linear noise looks obvious since the noise appears in a line. Preferably, the linear noise needs to be reduced to ⅕ to 1/10 of the point-like random noise found in each of the unit cells.

Here, as shown in Patent Literature 1, there is a trade-off problem between the size of the photoelectric converting element in a horizontal direction and the size of the gate of the amplifying transistor in a horizontal direction (gate width). Thus, it is difficult to reduce the random noise by making the gate width wider for the amplifying transistor.

The present invention is conceived in view of the above problems and has an object to provide a solid-state imaging device and a camera which develop lower noise.

In addition, the present invention has another object to provide a solid-state imaging device and a camera with high sensitivity in a small size.

### Solution to Problem

In order to achieve the above objects, a solid-state imaging device according to an aspect of the present invention includes unit cells which are arranged in two dimensions. Each of the unit cells includes: a photoelectric converting element which photoelectrically converts incident light; and amplifying transistors each of which has a gate that receives a voltage according to signal charges accumulated in the photoelectric converting element.

Thanks to the aspect, the amplifying transistors are arranged in parallel so that the thermal noise is successfully reduced. This feature contributes to implementing a solid-state imaging device which develops low noise. Compared with the case where one amplifying transistor is made larger in size, the aspect successfully gives a more flexible layout of the amplifying transistors per unit cell. This feature contributes to implementing a solid-state imaging device which develops low noise while maintaining its sensitivity without sacrificing the area for the photoelectric converting elements.

The unit cell may include photoelectric converting elements including the photoelectric converting element, and the photoelectric converting elements may share the amplifying transistors. The unit cell may include a transfer transistor which is provided between (i) the photoelectric converting element and (ii) gates of the amplifying transistors.

Thanks to the aspect, the photoelectric converting elements can share the amplifying transistors. This feature contributes to implementing a smaller solid-state imaging device in size.

The amplifying transistors may share one of a source region and a drain region.

Thanks to the aspect, the increase in the area for the unit cell can be reduced when two amplifying transistors are provided per unit cell. This feature contributes to implementing a smaller solid-state imaging device in size. When a source region is shared in the unit cell, the source region is made small so that the connection between the amplifying transistors and the column signal line is easier.

With respect to the shared one of the source region and the drain region for the amplifying transistors, a direction of a current flow between the source region and the drain region of one of the amplifying transistors and a direction of a current flow between the source region and the drain region of another one of the amplifying transistors may be symmetrical.

Thanks to the aspect, characteristics variation of the amplifying transistors among unit cells is successfully reduced. This feature contributes to implementing a solid-state imaging device which develops even lower noise.

In each of the unit cells that are neighboring with each other, the amplifying transistors may share one of a source region and a drain region.

Thanks to the aspect, the area for the unit cells can be reduced, which contributes to implementing a small solid-state imaging device in size.

All of drain regions and source regions for the amplifying transistors may be arranged in a line

Thanks to the aspect, multiple amplifying transistors can be arranged in parallel without affecting a region where photoelectric converting element is provided.

The gates of the amplifying transistors may be the same in width. The gates of the amplifying transistors may be the same in length.

Thanks to the aspect, characteristics variation of the amplifying transistors in a unit cell is successfully reduced. This feature contributes to implementing a solid-state imaging device which develops even lower noise.

The amplifying transistors may share a gate.

Thanks to the aspect, the connection between a floating diffusion and a gate is successfully maintained even though a contact failure develops on one of the gates of the amplifying transistors in a unit cell. Furthermore, the gates of the amplifying transistors can be designed more flexibly.

The gates of the amplifying transistors may be connected to each other via a signal line.

Thanks to the aspect the signal line for connecting the gates of the amplifying transistors is provided above the photoelectric converting element. This feature contributes to securing a lager area for the photoelectric converting element in a unit cell. The resulting solid-state imaging device is smaller in size with high sensitivity.

A camera according to another aspect of the present invention includes: a first chip on which a solid-state imaging device is formed, the solid-state imaging device including (i) unit cells arranged in two dimensions, and (ii) an AD conversion circuit which converts voltage signals, outputted from the unit cells, into digital signals; and a second chip on which a digital signal processing circuit is formed, the digital signal processing circuit processing the digital signals outputted from the first chip. Here, each of the unit cells includes: a photoelectric converting element which photoelectrically converts incident light; a transfer transistor which reads signal charges accumulated in the photoelectric converting element; and amplifying transistors each of which has a gate that receives a voltage according to signal charges accumulated in the photoelectric converting element.

Thanks to the aspect, a manufacturing process of the imaging unit can be separated from that of processing unit, which contributes to providing to a user more flexible use of the camera and lowering the cost of the camera.

### ADVANTAGEOUS EFFECTS OF INVENTION

The present invention successfully enlarges the size of the gate of each of the amplifying transistors, especially the width of the gate, while maintaining the size of a photoelectric converting element in a unit cell. This feature contributes to reducing random noise which develops in the unit cell and a constant current circuit. Hence, a solid-state imaging device and a camera implemented based on the present invention can have high sensitivity and low noise. Compared with capturing a still image, capturing a moving image causes restrictions time-wise. This problem makes it difficult for a camera with a moving image mode, such as a surveillance camera and a car-mounted camera, to reduce the effect of noise through correction. Thus, the present invention is highly practical since the present invention successfully reduce noise itself without correction.

### BRIEF DESCRIPTION OF DRAWINGS

These and other objects, advantages and features of the invention will become apparent from the following description thereof taken in conjunction with the accompanying drawings that illustrate a specific embodiment of the present invention.

FIG. 1 shows a schematic structure of a camera according to Embodiment 1 of the present invention.

FIG. 2 shows a detailed structure of a solid-state imaging device according to Embodiment 1.

FIG. 3 shows a circuit diagram exemplifying a structure of a column amplifier according to Embodiment 1.

FIG. 4 shows a circuit diagram exemplifying a structure of a signal holding capacitor and a signal holding switch according to Embodiment 1.

FIG. 5 shows a circuit diagram exemplifying a structure of a unit cell according to Embodiment 1.

FIG. 6 shows a plan pattern view of a first layer exemplifying an arrangement of elements and a layout of wiring of the unit cell according to Embodiment 1.

FIG. 7 shows a plan pattern view of a second layer exemplifying an arrangement of elements and a layout of wiring of the unit cell according to Embodiment 1.

FIG. 8 depicts a cross-sectional view (cross-sectional view taken from line A-A″ in FIG. 6) of the unit cell according to Embodiment 1.

FIG. 9 depicts a timing diagram showing how to drive the solid-state imaging device according to Embodiment 1.

FIG. 10 shows a plan pattern view of a first layer exemplifying an arrangement of elements and a layout of wiring of the unit cell according to Modification 1 of Embodiment 1.

FIG. 11 shows a plan pattern view of a first layer exemplifying an arrangement of elements and a layout of wiring of the unit cell according to Modification 2 of Embodiment 1.

FIG. 12 shows a plan pattern view of a first layer exemplifying an arrangement of elements and a layout of wiring of the unit cell according to Modification 3 of Embodiment 1.

FIG. 13 shows a plan pattern view of a first layer exemplifying an arrangement of elements and a layout of wiring of the unit cell according to Modification 4 of Embodiment 1.

FIG. 14 shows a plan pattern view of a first layer exemplifying an arrangement of elements and a layout of wiring of the unit cell according to Modification 5 of Embodiment 1.

FIG. 15 shows a plan pattern view of a second layer exemplifying an arrangement of elements and a layout of wiring of the unit cell according to Modification 5 of Embodiment 1.

FIG. 16 shows a plan pattern view of a first layer exemplifying an arrangement of elements and a layout of wiring of the unit cell according to Modification 5 of Embodiment 1.

FIG. 17 shows a plan pattern view of a first layer exemplifying an arrangement of elements and a layout of wiring of the unit cell according to Modification 6 of Embodiment 1.

FIG. 18 shows a plan pattern view of a second layer exemplifying an arrangement of elements and a layout of wiring of the unit cell according to Modification 6 of Embodiment 1.

FIG. 19 shows a plan pattern view of a third layer exemplifying an arrangement of elements and a layout of wiring of the unit cell according to Modification 6 of Embodiment 1.

FIG. 20 depicts a cross-sectional view (cross-sectional view taken from line A-A″ in FIG. 6) of the unit cell according to Modification 7 of Embodiment 1.

FIG. 21 depicts a cross-sectional view (cross-sectional view taken from line A-A″ in FIG. 6) of the unit cell according to Modification 8 of Embodiment 1.

FIG. 22 shows a circuit diagram exemplifying a structure of a unit cell according to Embodiment 2 of the present invention.

FIG. 23 shows a plan pattern view of a first layer exemplifying an arrangement of elements and a layout of wiring of the unit cell according to Embodiment 2.

FIG. 24 shows a plan pattern view of a first layer exemplifying an arrangement of elements and a layout of wiring of the unit cell according to Modification 9 of Embodiment 2.

FIG. 25 depicts a cross-sectional view of a modification of the unit cell according to Embodiments 1 and 2.

FIG. 26 shows a plan pattern view of a first layer exemplifying an arrangement of elements and a layout of wiring of the unit cell according to Modification 10 of Embodiment 2.

### DESCRIPTION OF EMBODIMENTS

Hereinafter, embodiments of the present invention are detailed with reference to the drawings.

### Embodiment 1

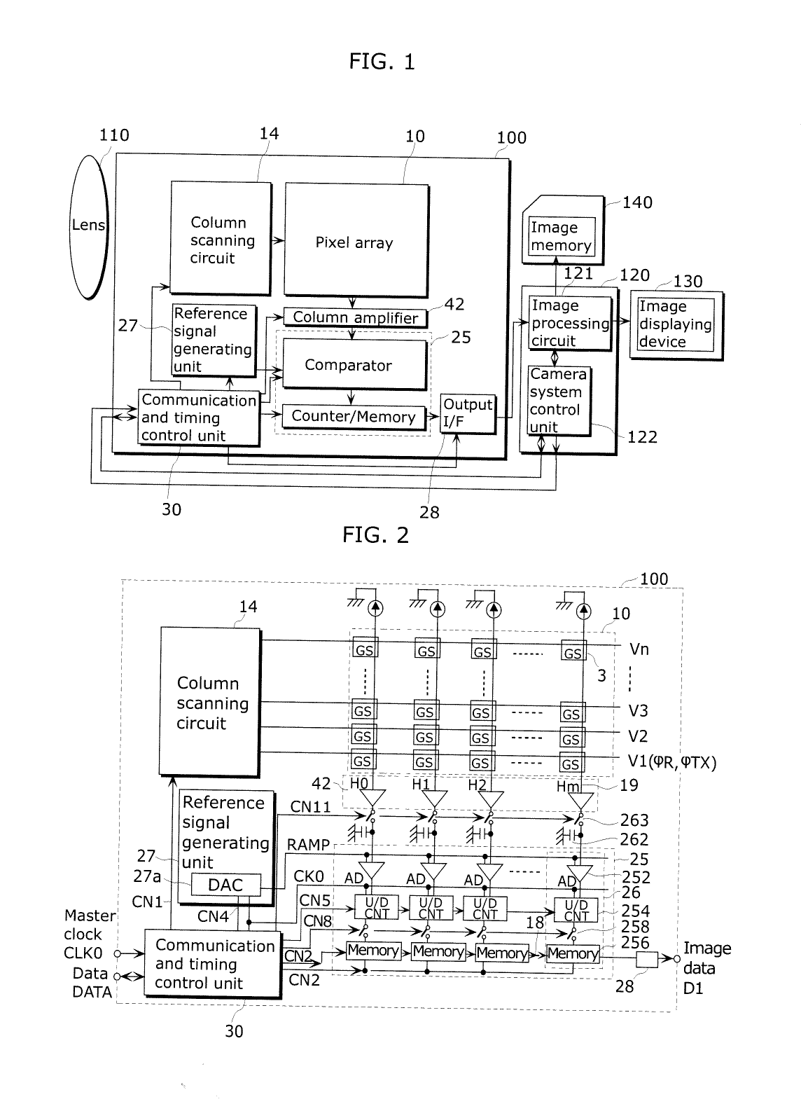

FIG. 1 shows a schematic structure of a camera according to Embodiment 1. FIG. 2 shows a detailed structure of a solid-state imaging device 100 according to Embodiment 1.

The camera includes the solid-state imaging device 100, a lens 110, a Digital Signal Processing circuit (DSP) 120, an image displaying device 130, and an image memory 140.

The camera receives light from outside via the lens 110, and the received light is converted into a digital signal and outputted to the DSP 120 by the soled-state imaging device 100. Then, the outputted digital signal is processed by the DSP 120. The processed signal is outputted to and stored in the image memory 140 as a video signal. The processed signal is also outputted to the image displaying device 130 as a video signal and displayed as an image.

The DSP 120 includes an image processing circuit 121 and a camera system control unit 122. The image processing circuit 121 reduces noise of the outputted signal from the solid-state imaging device 100, and generates the video signal. The camera system control unit 122 controls scan timing and gains of pixels in the solid-state imaging device 100. For example, the DSP 120 corrects a characteristic difference between pixels shared in a unit cell of the solid-state imaging device 100.

The solid-state imaging device 100 is formed in a single chip. The chip in which the solid-state imaging device 100 is formed differs from the chip in which the DSP 120 is formed. This structure makes it possible to separate a forming process of the solid-state imaging device 100 and that of the DSP 120 so as to separate the manufacturing process of an imaging unit and that of a processing unit. This feature contributes to reducing manufacturing processes and the costs. Moreover, this structure makes it possible to set timing control, gain control, and image processing for each of user's needs. This feature allows the user to operate the camera more flexibly.

The solid-state imaging device 100 is a CMOS solid-state imaging device, and includes a pixel unit (pixel array) 10, a column scanning circuit (row scanning circuit) 14, a communication and timing control unit 30, an analogue-digital converting (AD) circuit 25, a reference signal generating unit 27, an output I/F 28, signal holding switches 263, signal holding capacitors 262, and a column amplifier 42.

The pixel unit 10 includes unit cells 3 arranged two dimensionally (in a matrix) on a well of a semiconductor substrate. Each of the unit cells 3 includes pixels (photoelectric converting elements). Each of the unit cells 3 is connected to (i) a signal line which is controlled by the column scanning circuit 14 and (ii) a column signal line 19 which transmits voltage signals from the unit cells 3 to the AD converting circuit 25.

The column scanning circuit 14 scans the unit cells 3 for each of rows in a column direction, and selects a row of the unit cells 3 that output the voltage signals to the column signal line 19.

The communication and timing control unit 30 receives a master clock CLK0 and data DATA inputted via an external terminal, generates various kinds of internal clocks, and controls the reference signal generating unit 27 and the column scanning circuit 14, and so on.

The reference signal generating unit 27 includes a digital-analogue converter (DAC) 27a which supplies a reference voltage RAMP for AD conversion to a column AD circuit 26 of the AD converting circuit 25.

The column amplifier 42, each of the signal holding switches 263, and each of the signal holding capacitors 262 are provided to a corresponding one of columns of the unit cells 3. The column amplifier 42 amplifies the voltage signals outputted from the unit cells 3. The signal holding capacitors 262 hold the amplified voltage signals transmitted via the signal holding switches 263.The column amplifier 42 can amplify the voltage signals of the unit cells 3, which contributes to improving S/N, and switching gains.

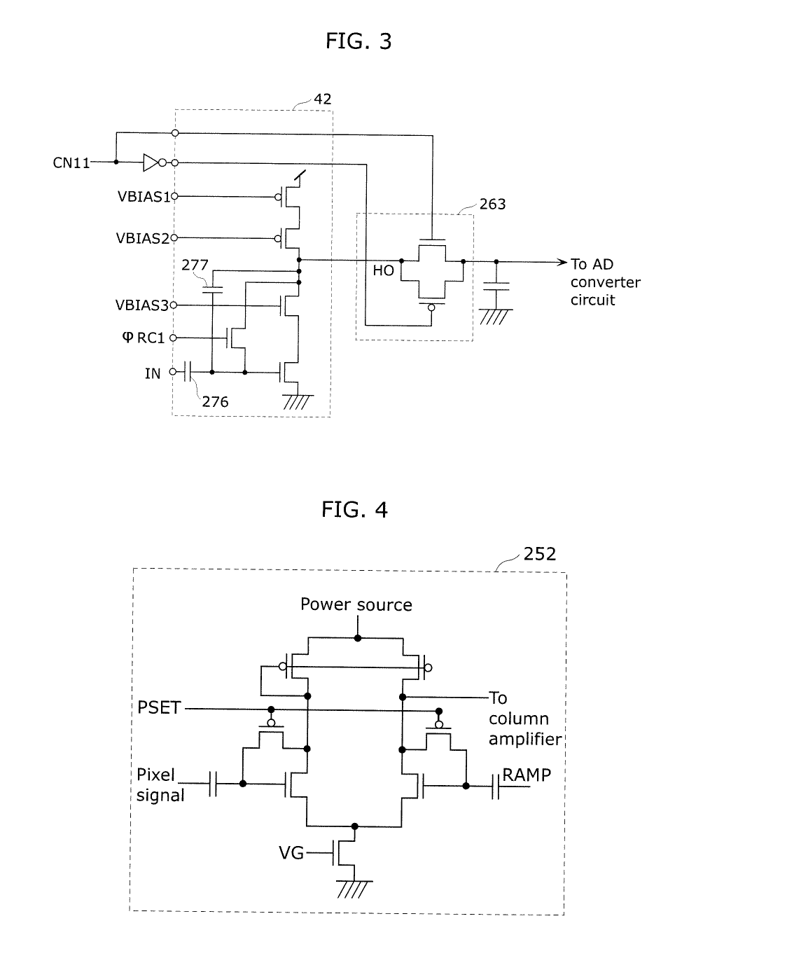

The column amplifier 42 is, for example, a common-source amplifier as shown in the circuit diagram in FIG. 3. The column amplifier 42 determines a gain of the amplifier based on the ratio between capacitor elements 276 and 277. It is noted that FIG. 3 is an example of the circuit. Any configuration is acceptable as far as the column amplifier 42 is an analogue amplifier for amplifying the voltage signals of the unit cells 3.

Each signal holding capacitor 262 and signal holding switch 263 includes, for example, a pair of an Nch transistor and a Pch transistor as shown in the circuit diagram in FIG. 4. The pair of the Nch transistor and Pch transistor makes possible to conduct the voltage signals of the column signal line 19 from the ground level to the power supply level without a voltage drop. It is noted that FIG. 4 is an example of the circuit. When the voltage level of the column signal line 19 does not shift from the ground level to the power supply level, the signal holding capacitor 262 and the signal holding switch 263 may include only one of the Nch transistor and the Pch transistor, depending on the voltage level.

The AD converting circuit 25 includes column analogue-digital converter (AD) circuits 26 each provided to a corresponding one of the columns of the unit cells 3. Using the reference voltage RAMP generated by the DAC 27a, the column AD circuit 26 converts the analogue voltage signals, outputted from the unit cells 3 and held in the signal holding capacitor 262, into digital signals.

The column AD circuit 26 includes a voltage comparing unit 252, a switch 258, and a data storage unit 256. The voltage comparing unit 252 compares each of the analogue voltage signals with the reference voltage RAMP. Here, the analogue voltage signals are outputted from the unit cell 3 and obtained via the column signal line 19 (H0, H1, . . . ) and the signal holding capacitor 262. The data storage unit 256 is a memory holding (i) a time period for which the voltage comparing unit 252 ends the comparison and (ii) a counting result by a counting unit 254.

One of the input terminals for a voltage comparing unit 252 receives, in common with the input terminal for another voltage comparing unit 252, receives the stepped reference voltage RAMP generated by the DAC 27a. The other one of the input terminals (i) connects to a signal holding capacitor 262 provided to a corresponding one of the columns, and (ii) receives voltage signals from the pixel unit 10. The output signals of the voltage comparing unit 252 are supplied to the counting unit 254.

The voltage comparing unit 252 is a difference input amplifier, as shown in the circuit diagram in FIG. 4 for example. It is noted that the structure of the voltage comparing unit 252 shall not be limited to the one in FIG. 4 as far as the voltage comparing unit 252 carries out an AD conversion on the voltage signals from the unit cells 3.

As soon as the reference voltage RAMP is supplied to the voltage comparing unit 252, the column AD circuit 26 starts counting (number counting) clock signals. Then, the column AD circuit 26 carries out the AD conversion by continuing the counting until pulse signals are obtained by the voltage comparing unit 252 comparing the reference voltage RAMP with the analogue voltage signals inputted via the signal holding capacitor 262.

Along with the AD conversion, the column AD circuit 26 obtains, from pixel signals in a voltage mode (voltage signals) provided via the signal holding capacitor 262 and set, a difference between a signal level immediately after the reset of a pixel (noise level) and a true (based on an amount of receipt light) signal level Vsig. This feature makes it possible to remove from the voltage signals a noise signal component referred to as Fixed Pattern Noise (FPN) and reset noise.

It is noted that the column AD circuit 26 downcounts the noise level and upcounts the signal level so as to obtain only the true signal level Vsig. The signals that are digitalized by the column AD circuit 26 are inputted to the output I/F 28 via a row signal line 18.

Thanks to this structure of the solid-state imaging device 100, the pixel unit 10 sequentially outputs the voltage signals for each row of the unit cells 3.Then, one image for the pixel unit 10; that is a frame of image, is displayed with an assemble of the voltage signals for the entire pixel unit 10.

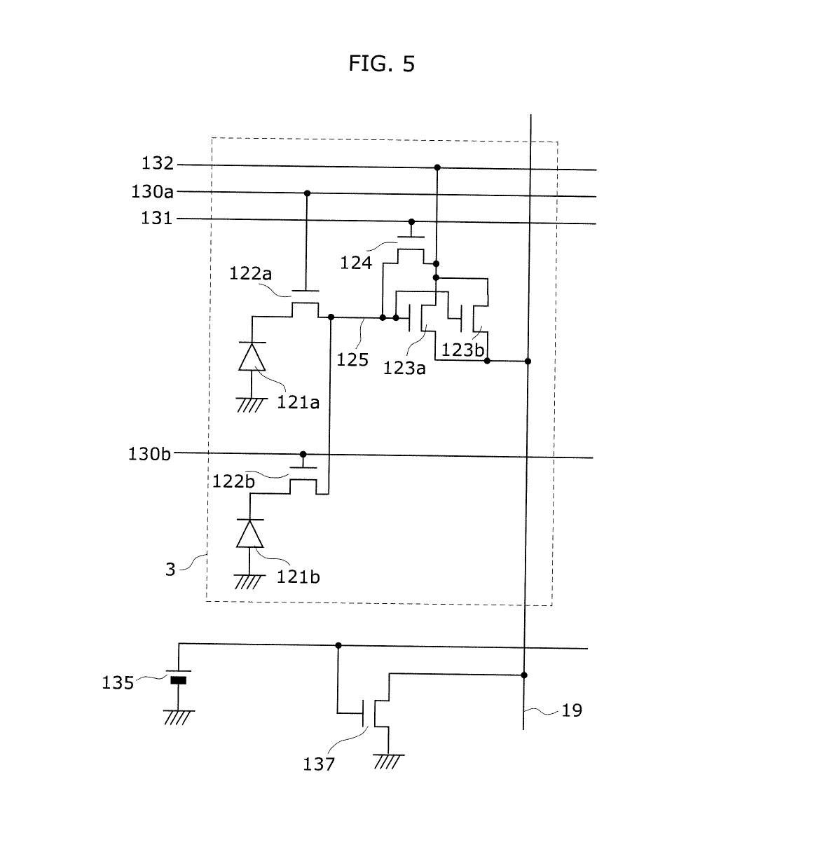

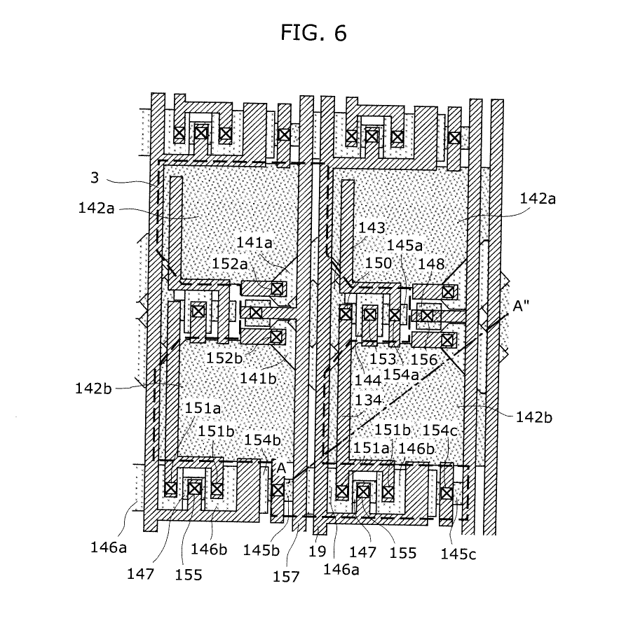

FIG. 5 shows a circuit diagram exemplifying a structure of a unit cell 3.

As circuit elements, each of the unit cells 3 includes, for example, photoelectric converting elements 121a and 121b, transfer transistors 122a and 122b, a floating diffusion (FD) 125, amplifying transistors 123a and 123b, and a reset transistor 124. Here, each unit cell 3 includes two photoelectric converting elements 121a and 121b; that is, two pixels. One of the features of the present invention is that amplifying transistors 123a and 123b are arranged in parallel.

Each unit cell 3 is connected to the column signal line 19 working as a conductive line, to transfer control signal lines 130a and 130b, to a reset signal line 131, and a power line 132. The column signal line 19 is shared with the unit cells 3 provided in the same column. The transfer control signal lines 130a and 130b, and the reset signal line 131 are shared with the unit cells 3 arranged in a row direction.

The photoelectric converting elements 121a and 121b have their anodes grounded, and convert incoming light into charges (electrons or holes) depending on an amount of the incoming light, and accumulate the converted charges. One of the photoelectric converting elements 121a and 121b is electrically connected in common to the gates of the amplifying transistors 123a and 123b.

Each of the transfer transistors 122a and 122b is provided between (i) the FD 125 and (ii) the photoelectric converting elements 121a and 121b, so that the transfer transistors 122a and 122b correspond to the photoelectric converting elements 121a and 121b, respectively. Each of the transfer transistors 122a and 122b reads signal charges generated by one of the respectively corresponding photoelectric converting elements 121a and 121b, and transfers the charges to the FD 125. Each of the transfer transistors 122a and 122b (i) has the source connected to the cathode of a respectively corresponding one of the photoelectric converting elements 121a and 121b, (ii) has the gate connected to a respectively corresponding one of the transfer control signal lines 130a and 130b, and (iii) has the drain connected to the FD 125 and the gates of the amplifying transistors 123a and 123b.

The transfer transistor 122a is provided between (i) the photoelectric converting element 121a and (ii) the gates of the amplifying transistors 123a and 123b. The transfer transistor 122b is provided between (i) the photoelectric converting element 121b and (ii) the gates of the amplifying transistors 123a and 123b. When a potential of the transfer control signal line 130a goes high, the transfer transistor 122a transfers to the FD 125 the charges accumulated in the photoelectric converting element 121a. When a potential of the transfer control signal line 130b goes high, the transfer transistor 122b transfers to the FD 125 the charges accumulated in the photoelectric converting element 121b.

The FD 125 accumulates the signal charges to be transferred from one of the selected photoelectric converting elements 121a and 121b through respectively corresponding one of the transfer transistors 122a and 122b. The potential of the FD 125 is determined based on the amount of the transferred signal charges. The FD 125 is electrically connected in common to the gates of the amplifying transistors 123a and 123b, as well as to the photoelectric converting elements 121a and 121b.

Moreover, the signal charges accumulated into the photoelectric converting elements 121a and 121b are read to the FD 125, and the voltage for the FD 125 changes to the degree corresponding to the intensity of the incoming light. The changed voltage is applied to the gates of the amplifying transistors 123a and 123b. The gates of the amplifying transistors 123a and 123b have the voltage applied to, according to the signal charges accumulated in the photoelectric converting elements 121a and 121b.

Each of the amplifying transistors 123a and 123b has (i) the gate connected to the FD 125, (ii) the drain connected to the power line 132, and (iii) the source connected to the column signal line 19. Each of the amplifying transistors 123a and 123b outputs to the column signal line 19 a signal voltage corresponding to the amount of the signal charges accumulated in one of the photoelectric converting elements 121a and 121b. In other words, the amplifying transistors 123a and 123b output a signal voltage corresponding to the potential of one FD 125.

The reset transistor 124 has (i) the source connected to the FD 125 and to the gate of each of the amplifying transistors 123a and 123b, (ii) the drain connected to the power line 132, and (iii) the gate connected to the reset signal line 131. When the reset signal line 131 goes high, the reset transistor 124 resets (initializes) the potential of the FD 125 to the potential of the power line 132. Here, the potential of the FD 125 is the potential of the gate of each of the amplifying transistors 123a and 123b.

Each of the transfer transistors 122a and 122b, the amplifying transistors 123a and 123b, and the reset transistor 124 is an N-type MOS transistor. It is noted that each of the transfer transistors 122a and 122b, the amplifying transistors 123a and 123b, and the reset transistor 124 may also be a P-type MOS transistor.

In the unit cell 3 shown in FIG. 5, the drains of the transfer transistor 122a and 122b are connected to each other to form a single FD 125. In other words, the photoelectric converting elements 121a and 121b share the FD 125, the reset transistor 124, and the amplifying transistors 123a and 123b.

The column scanning circuit 14 selects pixels in a row to be read in the pixel unit 10. In order to select the pixels, the column scanning circuit 14 (i) controls, through the reset transistors 124, the potentials of the FDs 125 in the unit cells 3 including the pixels in the row to be read, so that both of the amplifying transistors 123a and 123b turn on, and then (ii) activates transfer transistors corresponding to the pixels in the row to be read. Other pixels than the row to be read in the unit cells 3 are not selected since transfer transistors corresponding to the other pixels are kept in a non-active state. Moreover, in the unit cells 3 that do not include the pixels in the row-to-be-read, the potentials of the FDs 125 are controlled through the reset transistors 124 so that the amplifying transistors 123a and 123b do not turn on.

The unit cells 3 are two-dimensionally arranged on the well of the semiconductor substrate. Here, the unit cells 3 arranged in a column are connected in parallel to a corresponding one of the column signal lines 19. The column signal line 19 transmits signal voltages outputted from the unit cells 3. The column signal line 19 connects to a constant current transistor 137. The gate of the constant current transistor 137 is biased with a constant voltage by a bias supply 135, and works as a constant current source.

In the unit cell 3, when the potential of the FD 125 is set to the potential that turns on the amplifying transistors 123a and 123b, the amplifying transistors 123a and 123b, and the constant current transistor 137 form a source follower. Hence, outputted to the column signal line 19 is the potential that drops from the potential of each of the gates of the amplifying transistors 123a and 123b by a source-gate voltage.

In the solid-state imaging device 100 according to Embodiment 1, two amplifying transistors 123a and 123b are arranged in parallel in a unit cell 3. Thus, for example, the width W of the gate of an amplifying transistor in the unit cell 3 can be twice as wide. As a result, the thermal noise which develops in the amplifying transistor can be represented as Vn̂2=8k×T/(3 gm), gm=(μ×Cox) W/L×(Vgs−Vth). 1/f noise can be represented as Vn̂2=K/(Cox×W×L×f). Consequently, the thermal noise and the 1/f noise can be reduced to 1/√2. Here, k is the Boltzmann constant, T is an absolute temperature, gm is a mutual conductance, μ is mobility, Cox is a capacitance of a gate oxide layer per unit area, W is a gate width of the transistor, L is a gate length of the transistor, Vgs is a gate-source potential, and Vth is a threshold voltage of the transistor. Here, K is a constant for the trap density of the transistor, and f is a frequency.

Moreover, horizontal linear random noise, which develops in the constant current transistor 137 and the bias supply 135, can be reduced to 1/√2. In other words, when ΔV is the noise developed on the gate of the constant current transistor 137, the current variation ΔI caused by the development of the noise can be represented as ΔI=gm1×ΔV, using the mutual conductance gm1 of the constant current transistor 137. With respect to the current variation ΔI, an output conversion noise ΔVn of an amplifying transistor can be represented as ΔVn=√(β1/β2)×ΔV, and β2=(μ×Cox)×W/L from ΔVn=ΔI/gm2=gm1/gm2×ΔV and gm=(μ×Cox) W/L×(Vgs−Vth)=√(2×β×I), using the mutual conductance gm of the amplifying transistor. Consequently, when the gate width W for the amplifying transistor is made twice as wide, the horizontal linear random noise caused by the constant current source can be reduced to 1/√2. Compared with point-like random noise developing in the unit cell 3, the linear noise looks obvious since the noise appears in a line. Because of the characteristics of an image sensor, such linear noise needs to be reduced to 1/10 of the point-like random noise. Hence, it is highly effective to reduce the linear random noise.

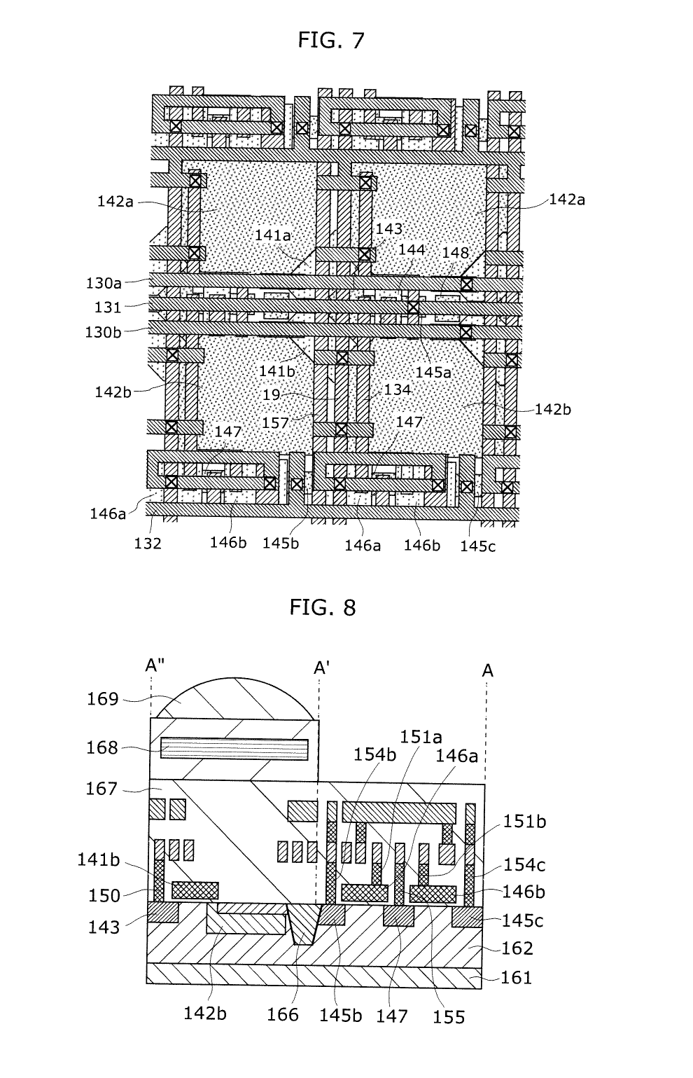

FIGS. 6 and 7 show plan pattern views exemplifying arrangements of elements and layouts of wiring of the unit cell 3 illustrated in FIG. 5. It is noted that FIG. 6 illustrates a plan pattern view of the first layer, and FIG. 7 illustrates a plan pattern view of the second layer above the first layer.

The FD 125 is formed of an FD region 143. A gate 141a of the transfer transistor 122a is provided between the FD region 143 and a photoelectric converting region (active region) 142a of the photoelectric converting element 121a. Similarly, a gate 141b of the transfer transistor 122b is provided between the FD region 143 and a photoelectric converting region 142b of the photoelectric converting element 121b.

The amplifying transistor 123a is formed of a gate 146a, a source region 147, and a drain region 145b. The amplifying transistor 123b is formed of a gate 146b, a source region 147, and a drain region 145c.

The reset transistor 124 is formed of a gate 144, the FD region 143, and a drain region 145a.

The gates 141a, 141b, 144, 146a, and 146b are made of, for example, polysilicon.

The gate 141a of the transfer transistor 122a is connected to the transfer control signal line 130a via a contact part 152a. Similarly, the gate 141b of the transfer transistor 122b is connected to the transfer control signal line 130b via a contact part 152b.

The gate 144 of the reset transistor 124 is connected to the reset signal line 131 via a contact part 153.

The FD region 143, the gate 146a of the amplifying transistor 123a, and the gate 146b of the amplifying transistor 123b are electrically connected to one another via contact parts 150, 151a, and 151b, and a conductive line 134.

The drain region 145a of the reset transistor 124, the drain region 145b of the amplifying transistor 123a, and the drain region 145c of the amplifying transistor 123b are connected to a conductive line; namely the power line 132, via contact parts 154a, 154b, and 154c.

The source regions 147 for the amplifying transistors 123a and 123b are connected to the same column signal line 19 via a contact part 155.

One well contact region 148 is placed for one unit cell 3. The well contact region 148 is electrically connected to a well voltage supply line 157 via a well contact part 156. Here, the well voltage supply line 157 extends in a column direction and is used for supplying a well voltage; namely a ground level, for example. This structure makes it possible to fix the well voltage.

In the unit cell 3, the amplifying transistors 123a and 123b are arranged so that all the drain regions and the source region; namely the drain regions 145b and 145, and the source region 147, are arranged in a line. This arrangement contributes to reducing the arrangement area for the amplifying transistors 123a and 123b.

In the unit cell 3, the amplifying transistors 123a and 123b share the source region 147. This arrangement makes it possible to secure a larger area for the amplifying transistors 123a and 123b. This feature makes it possible to increase the sizes of the gate widths W for the amplifying transistors, which contributes to reducing random noise.

In the unit cell 3, the gate widths W and the gate lengths L are all the same in size for the amplifying transistors 123a and 123b. This feature contributes to reducing variation in the threshold voltage Vth caused by the variation in the sizes of the amplifying transistors 123a and 123b. Here, when Vin is an input to a source follower circuit, Vout is an output of the source follower circuit, α is a gain (approximately 0.9 times) of the source follower circuit, Vout=α (Vin−Vth) is held. Reduction of the variation in the threshold voltage Vth can reduce the variation in the voltage Vout outputted to the column signal line 19.This contributes to securing a dynamic range for the source follower circuit and to reducing variation in the dynamic range.

It is noted that the gate widths W and the gate lengths L are all the same in size for the amplifying transistor 123a and 123b; instead, either the gate widths W or the gate lengths L may be the same in size.

With respect to the shared source region 147 for the amplifying transistors 123a and 123b in the unit cell 3, a direction of a current flow between the source region 147 and the drain region 145b of one of the amplifying transistors 123a and 123b and a direction of a current flow between the source region 147 and the drain region 145c of another one of the amplifying transistors 123a and 123b are symmetrical. This feature contributes to reducing the variation in the voltage Vout to be outputted to the column signal line 19. Here, the width/length sizes of the transistors need to be the same in order to avoid bias of the voltage Vout.

In the unit cell 3, the gate 146a of the amplifying transistor 123a and the gate 146b of the amplifying transistor 123b are electrically connected to each other with a signal line which is a metal line. This feature makes it possible to reduce the length of the gates 146a and 146b in a column direction, which contributes to increasing the gate widths W for the amplifying transistors. The layout around the contact part 155 successfully avoids arranging gates one above the other. This feature contributes to securing the room for the contact part 155.

In the unit cell 3, the amplifying transistors 123a and 123b are disposed across the pixels with respect to the gates 141a and 142b of the transfer transistors 122a and 122b, so that the amplifying transistor 123a and 123b are provided apart from the transfer transistor 122a and the 122b. This feature makes it possible to adjust the threshold voltage Vth for the amplifying transistors 123a and the 123b without affecting the characteristics in reading the signal charges by the transfer transistors 122a and 122b from the pixels. For example, thermal noise is represented as Vn̂2=8k×T/(3 gm), gm=(μ×Cox) W/L×(Vgs−Vth). Here, as the threshold voltage Vth is made lower, gm can be made higher and the thermal noise can be reduced.

In the unit cell 3, the channels of the amplifying transistors 123a and 123b are embedded channels. Consequently, the voltage signals become insusceptible to crystal defects between an oxide film and a silicon interface, which contributes to reducing the Random Telegraph Noise (RTS noise) which is a kind of 1/f noise.

In each of the unit cells 3 that are neighboring and arranged in a row direction, the amplifying transistors 123a and 123b share the drain region 145b, which contributes to securing a large area for the amplifying transistors 123a and 123b. This feature makes it possible to increase the sizes of the gate widths W for the amplifying transistors, which contributes to reducing random noise.

In the unit cell 3, the amplifying transistors 123a and 123b are provided so that the gate areas of the amplifying transistors are successfully increased. This feature makes it possible to give the amplifying transistors a more flexible layout and process (manufacturing) condition without affecting the read characteristics of the pixels.

FIG. 8 depicts a cross-sectional view (cross-sectional view taken from line A-A″ in FIG. 6) of the unit cell 3.

The photoelectric converting elements and the transistor included in the unit cell 3 are formed in a P-well 162 within an N-type substrate 161. The source region 147, the drain regions 145b and 145c of the amplifying transistors 123a and 123b, and the FD region 143 are formed of an N-type active region. The gates 141a, 141b, 144, 146a, and 146b are made of, for example, polysilicon.

The unit cell 3 includes an interlayer insulating film 167 having a signal line and contact parts 150, 154b, 151a, 151b, and 151c. Over the interlayer insulating film 167, a color filter 168 and a micro lens 169 are formed to be provided above the photoelectric converting region 142b. The incoming light collected by the micro lens 169 is separated into each of the color components R,G,B by the color filter 168, and enters the photoelectric converting region 142b.

In the unit cell 3, an element separation region 166, such as the Shallow Trench Isolation (STI) and the Local Oxidization On Silicon (LOCOS), is formed between the photoelectric converting elements and the transistors.

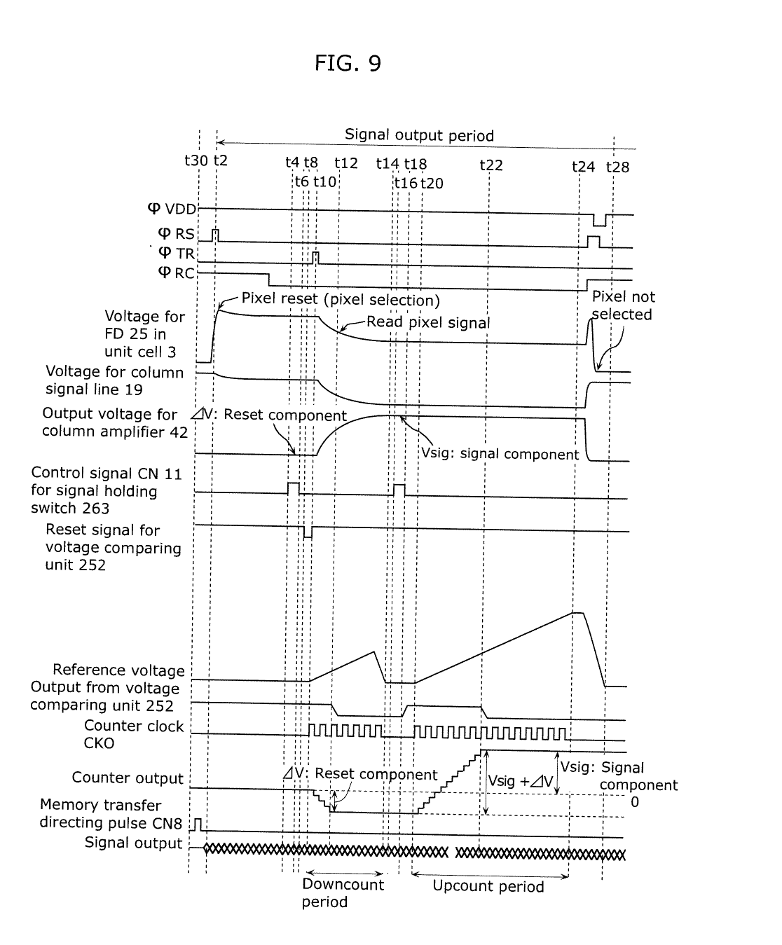

FIG. 9 depicts a timing diagram showing how to drive the solid-state imaging device 100 according to Embodiment 1.

For the first reading, the communication and timing control unit 30 resets the count value of the counting unit 254 to the initial value “0”, and sets the counting unit 254 to the downcount mode. Then, when the first reading from a unit cell 3 in any given row to the column signal line 19 (H1, H2, . . . ) stabilizes, the communication and timing control unit 30 applies a control signal CN 11 of the signal holding switch 263 with the timing t4, turns on the signal holding switch 263, and inputs a reset signal of the unit cell 3 into a signal holding capacitor 262.

Moreover, when the input of the signal into the signal holding capacitor 262 stabilizes, the communication and timing control unit 30 stops the application of the control signal CN 11 of the signal holding switch 263 with the timing t6, turns off the signal holding switch 263, and causes the signal holding capacitor 262 to hold the reset signal (ΔV of a signal voltage for a reset component) of the unit cell 3.

Furthermore, the communication and timing control unit 30 supplies to the reference signal generating unit 27 control data CN 4 for generating a reference voltage RAMP. In response, the reference signal generating unit 27 inputs, to the input terminals RAMP of the voltage comparing unit 252, a comparison voltage (reference voltage) having a stepped waveform (RAMP waveform) which is temporally varied in an overall sawtooth wave form (ramp-shaped).The voltage comparing unit 252 compares the comparison voltage with the ΔV of the signal voltage for the reset component held in the signal holding capacitor 262.

Furthermore, as soon as the reference voltage is inputted to the input terminal RAMP of the voltage comparing unit 252, the counting unit 254 placed for each of the rows measures a comparison time at the voltage comparing unit 252. The measurement is carried out when the communication and timing control unit 30 provides a count clock CK0 to a clock terminal of the counting unit 254 in synchronization with (t10) the reference voltage outputted from the reference signal generating unit 27, and the counting unit 254 starts downcount at the initial value “0” as the first counting operation.

Moreover, the voltage comparing unit 252 compares the reference voltage from the reference signal generating unit 27 with the signal voltage for the reset component. When both the voltages become the same, the voltage comparing unit 252 inverts the output of the voltage comparing unit 252 from the H level to the L level (t12). The voltage comparing unit 252 compares the signal voltage based on the reset component ΔV with the reference voltage and counts the time length in a time axis direction in the time axis direction using the count clock CK0, in order to obtain a count value which corresponds to the amount of the reset component ΔV. In other words, the counting unit 254 starts the downcount when the RAMP waveform starts to vary and continues the downcount until the output of the voltage comparing unit 252 inverts, in order to obtain the count value which corresponds to the amount of the reset component ΔV.

Furthermore, when a predetermined downcount period elapses (t14), the communication and timing control unit 30 suspends the supply of the control data to the voltage comparing unit 252 and of the count clock CK0 to the counting unit 254. Hence, the voltage comparing unit 252 stops generating the ramp-shaped reference voltage RAMP.

At the first reading, the reset level of the signal voltage in the unit cell 3 is detected by the voltage comparing unit 252 for the counting, which means the reset component ΔV of the unit cell 3 is read.

Moreover, the downcount starts with the timing t10, and an AD conversion is carried out on the reset component ΔV. At the same time, a pixel reading pulse φTR for reading signal components accumulated in the unit cell 3 is applied, and a signal component of a pixel Vsig is outputted to the column signal line 19.

Here, the application of the control signal CN 11 of the signal holding switch 263 stops, the signal holding switch 263 is off, and the column signal line 19 to which the signal component Vsig is read and the signal holding capacitor 262 which holds the reset component ΔV are electrically disconnected to each other. Hence, even though the signal component Vsig is read to the column signal line 19, the reset component ΔV can be held in the signal holding capacitor 262. In addition, the reading of the signal component Vsig can be carried out in parallel with the AD conversion on the reset component ΔV.

Moreover, when the reading of the signal component Vsig and the AD conversion of the reset component ΔV ends, the second reading starts subsequently. In the second reading, the signal component Vsig is read, based on incoming light for each of the unit cells 3. The second reading differs from the first reading in that, in the second reading, the counting unit 254 is set to the upcount mode.

For the second reading, with the timing t14, the communication and timing control unit 30 resets the count value of the counting unit 254 to the initial value “0”. Then, when the second reading from a unit cell 3 in any given row to the column signal line 19 (H1, H2, . . . ) stabilizes, the communication and timing control unit 30 applies the control signal CN 11 of the signal holding switch 263 with the timing t16, turns on the signal holding switch 263, and inputs the signal component Vsig into the signal holding capacitor 262. When the input of the signal into the signal holding capacitor 262 stabilizes, the communication and timing control unit 30 stops the application of the control signal CN 11 of the signal holding switch 263 at the timing t18, turns off the signal holding switch 263, and causes the signal holding capacitor 262 to hold the signal component Vsig.

Moreover, when the reading of the signal component Vsig to the signal holding capacitor 262 stabilizes, the reference signal generating unit 27 inputs a reference voltage which is temporally varied in a stepped form so that the overall reference voltage is ramp-shaped. The voltage comparing unit 252 compares the reference voltage and the signal voltage of the signal component Vsig held in the signal holding capacitor 262.

Here, as soon as the reference voltage is inputted to the input terminals RAMP of the voltage comparing unit 252, the counting unit 254 starts upcount at the initial value “0” as the second counting in synchronization with the reference voltage (t20) provided from the reference signal generating unit 27, in order to measure a comparison time at the voltage comparing unit 252 using the counting unit 254.

Moreover, the voltage comparing unit 252 compares the reference voltage from the reference signal generating unit 27 with the signal voltage of the signal component Vsig held in the signal holding capacitor 262. When both the voltages become the same, the voltage comparing unit 252 inverts the output of the voltage comparing unit 252 from the H level to the L level (t22). In other words, the voltage comparing unit 252 compares the signal voltage based on the signal component Vsig with the reference voltage and counts the time length in the time axis direction using the count clock CK0, in order to obtain a count value which corresponds to the amount of the signal component Vsig. In other words, the counting unit 254 starts the upcount when the RAMP waveform starts to vary and continues the upcount until the output of the voltage comparing unit 252 inverts, in order to obtain the count value which corresponds to the amount of the signal component Vsig.

Furthermore, the AD-converted data is transmitted to and held in the data storage unit 256. Hence, before the operation of the counting unit 254 (t30), the counting result of the previous row is transmitted from the communication and timing control unit 30 to the data storage unit 256 based on a memory transfer directing pulse CN8. This feature makes it possible to carry out outputting signals from the data storage unit 256 to the DSP 120 via the output I/F 28 in parallel with counting by the counting unit 254 and reading.

In the above driving technique, the counting operation performed on the counting unit 254 includes the downcount for the first reading and the upcount for the second reading. Hence, subtraction is automatically performed in the counting unit 254, and only the Vsig signal component can be obtained as a count value, based on the counter value of 0.

Moreover, in the above driving technique, the column AD circuit 26 can also work as a Correlated Double Sampling (CDS) processing functioning unit, as well as a digital converting unit for converting an analogue pixel signal into digital pixel signal data.

As described above, in the solid-state imaging device 100 according to Embodiment 1, the unit cell 3 includes the photoelectric converting elements 121a and 121b sharing the amplifying transistors 123a and 123b. Specifically, in the unit cell 3, the drain of the transfer transistor 122a and the drain of the transfer transistor 122b are connected to each other to form a single FD 125. The photoelectric converting elements 121a and 121b share the FD 125, the reset transistor 124, and the amplifying transistors 123a and 123b.

This structure successfully makes the area, which transistors occupy in one unit cell 3, small and the numerical aperture (the ratio of an aperture area of a photoelectric converting element to the area of one unit cell 3) high. Consequently, this structure makes it possible to increase the amount of incoming light per unit area, and improves the sensitivity characteristics of the solid-state imaging device. Moreover, the higher the numerical aperture ratio is, the easier the control of the incoming light amount with respect to a required wavelength is. This feature successfully improves the spectral characteristics of the solid-state imaging device.

In particular, when the present invention is applied to a single-chip camera, the solid-state imaging device is equipped with a color filter, and needs to satisfy required characteristics of colors for each of R, G, B. Thus, spectral characteristics are important.

Furthermore, in the solid-state imaging device 100 according to Embodiment 1, the unit cell 3 includes the amplifying transistors 123a and 123b whose gates receive voltages corresponding to the signal charges accumulated in the photoelectric converting elements 121a and 121b. Specifically, in one unit cell 3, the amplifying transistors 123a and 122b are arranged in parallel. This structure makes it possible to implement a solid-state imaging device which develops low noise.

In other words, the present invention can achieve all of the sensitivity characteristics, the spectral characteristics, and the low noise performance of the solid-state imaging device in a high level.

### Modification 1

Here, Modification 1 according to Embodiment 1 shall be described.

Embodiment 1 describes that, in a unit cell, amplifying transistors share a source region. Modification 1 described that, in a unit cell, amplifying transistors share a source region.

Moreover, in Embodiment 1, the unit cell includes two amplifying transistors arranged in parallel. Instead, the unit cell in Modification 1 can have four amplifying transistors arranged in parallel. This structure contributes to decreasing the size of the gate length L of each of the amplifying transistors, and to further reducing horizontal linear noise. Hence, in the unit cell of Modification 1, amplifying transistors share a source region.

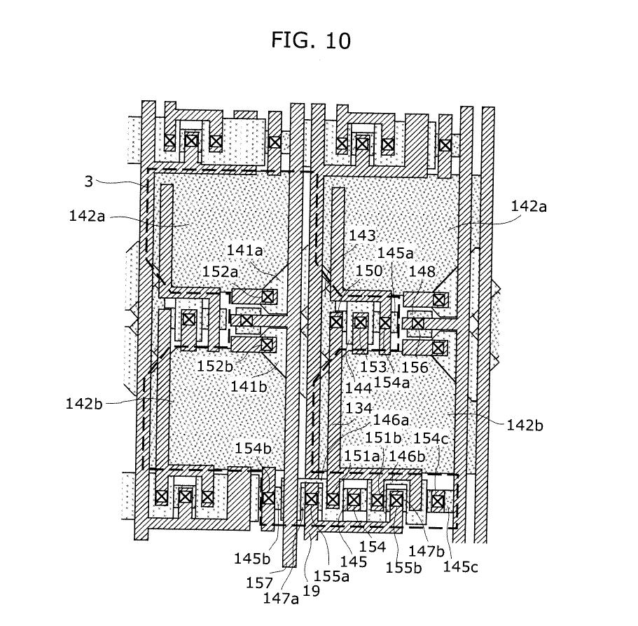

FIG. 10 shows a plan pattern view of a first layer exemplifying an arrangement of elements and a layout of wiring of the unit cell 3 according to Modification 1.

The four amplifying transistors include the gates 146a and 146b, source regions 147a and 147b, and the drain regions 145, 145b, and 145c.

The source regions 147a and 147b for the four amplifying transistors are connected to the column signal line 19 through one of contact parts 155a and 155b. Here, the contact parts 155a and 155b respectively correspond to the source regions 147a and 147b. The drain regions 145, 145b, and 145c for the four amplifying transistors are connected to the power line 132; namely a conductive line, through the contact parts 154, 154b, and 154c.

It is noted that in each of the adjacent unit cells 3 arranged in a row direction, the amplifying transistors may share a source region.

### Modification 2

Here, Modification 2 according to Embodiment 1 shall be described.

In each of the adjacent unit cells 3 arranged in a row direction according to Embodiment 1, the amplifying transistors share a drain region. However, in the case where a solid-state imaging device can employ a large semiconductor substrate and does not have to be downsized, each of the adjacent unit cells 3 arranged in a row direction does not have to share a drain region.

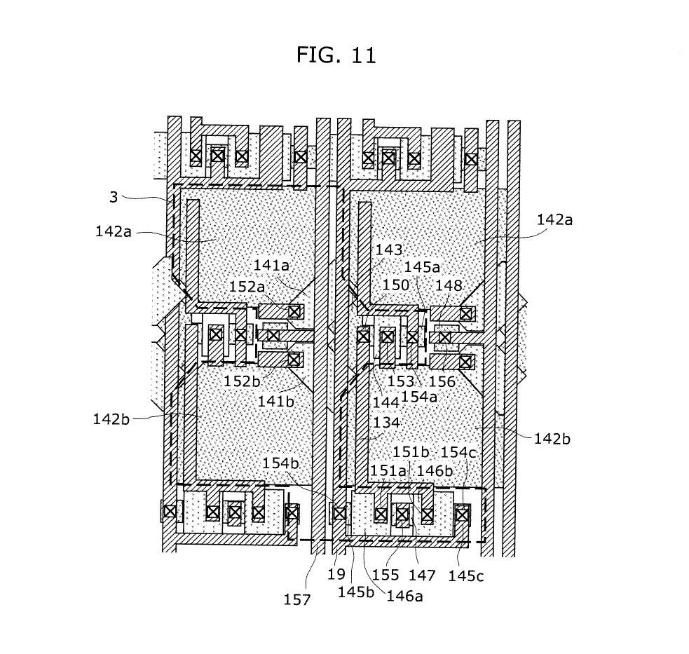

FIG. 11 shows a plan pattern view of a first layer exemplifying an arrangement of elements and a layout of wiring of the unit cell 3 according to Modification 2.

In each of the unit cells 3 arranged in a row direction, the amplifying transistors do not share the drain region 145b.

### Modification 3

Here, Modification 3 according to Embodiment 1 shall be described.

In Embodiment 1, each of the gates is separately provided for an amplifying transistor, and the gates are electrically connected to each other via the signal line. However, when the amplifying transistors share a gate, wiring is easier for the signal line connecting the sharing gates and the FD region. Moreover, multiple contacts can be provided between the sharing gates and the signal line, which contributes to reducing a defective contact rate. Hence, in Modification 3, the amplifying transistors share the gate in a unit cell.

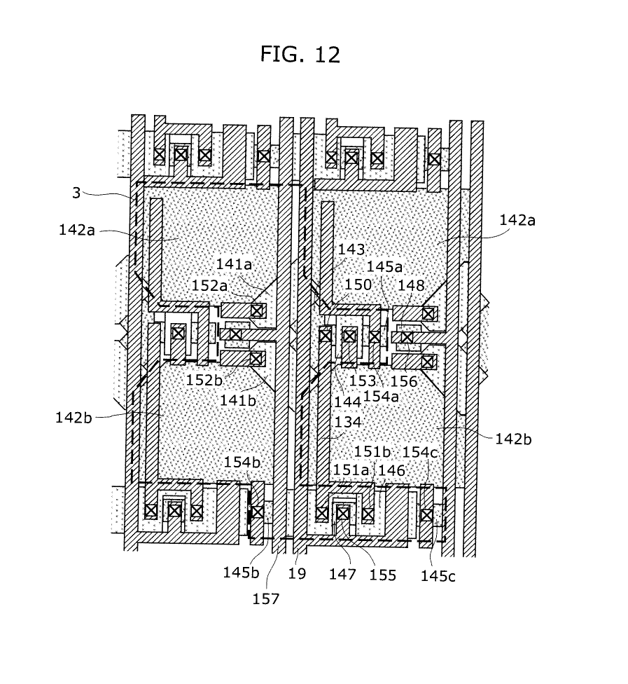

FIG. 12 shows a plan pattern view of a first layer exemplifying an arrangement of elements and a layout of wiring of the unit cell 3 according to Modification 3.

In the unit cell 3, the amplifying transistors share a gate 146. The FD region 143 and the gate 146 of the amplifying transistors are electrically connected to each another via the contact parts 150, 151a and 151b, and the conductive line 134.

### Modification 4

Here, Modification 4 according to Embodiment 1 shall be described.

In Embodiment 1, the contacts of the gates for the amplifying transistors are arranged on a straight line in which a source region and a drain region, both corresponding to the contacts, are aligned. However, the contacts are provided not above the channel. Such a structure can reduce damage to the channel and deterioration in leakage characteristics. Hence, in Modification 4, the contacts for the amplifying transistors may not be provided on the straight line in which the source region and the drain region are aligned.

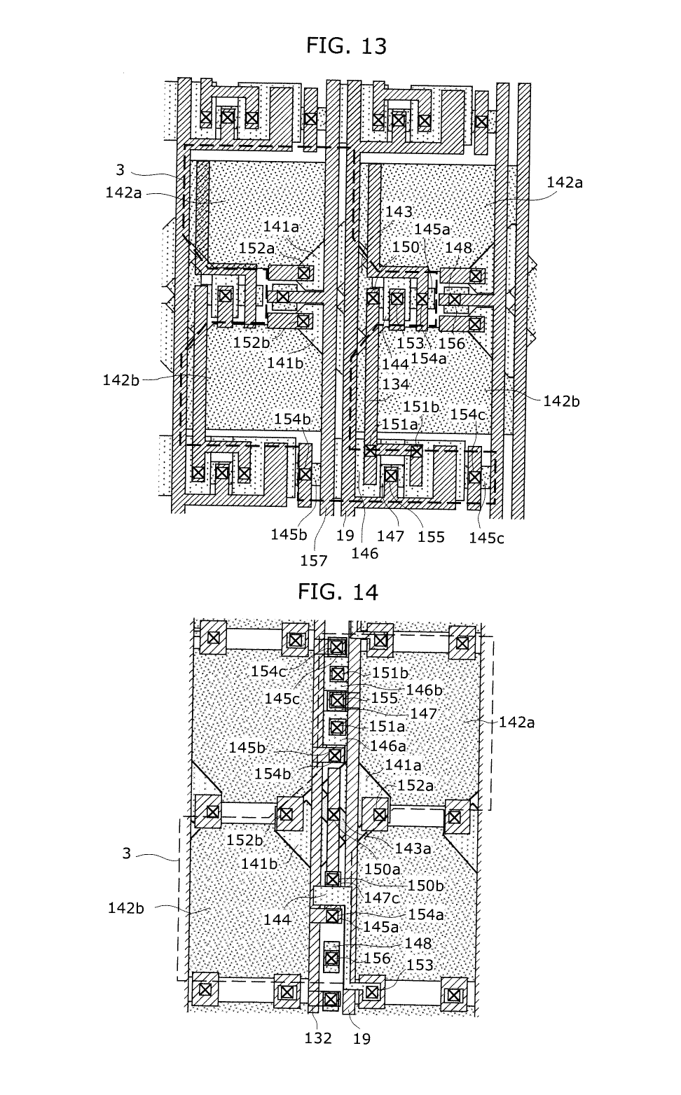

FIG. 13 shows a plan pattern view of a first layer exemplifying an arrangement of elements and a layout of wiring of the unit cell according to Modification 4.

In the unit cell 3, the amplifying transistors share a gate 146. The contact parts 151a and 151b, electrically connecting the gate 146 for the amplifying transistors with the conductive line 134, are provided on a region other than the straight line in which the source region and the drain region are aligned. In other words, the contact parts 151a and 151b are provided on a region other than the above of the channel of the amplifying transistors.

### Modification 5

Here, Modification 5 according to Embodiment 1 shall be described.

In Embodiment 1, the amplifying transistors in a unit cell are arranged in a horizontal direction (row direction). However, the amplifying transistors in the unit are arranged in a vertical direction (column direction), so that a pixel can be formed horizontally long. Since a pixel unit is horizontally long, forming the pixel long in a row direction contributes to improving the characteristics of an incidence angle of obliquely entering light into the pixel. Such an effect is more apparent when, for example, the feature is utilized for a hi-vision (16:9) image sensor than for an image sensor of a 4:3 pixel. Hence, in Modification 5, the amplifying transistors in a unit cell are arranged in a vertical direction (column direction).

It is noted that in Embodiment 1 the pixels arranged in a column direction form a single unit cell. In Modification 5, instead, the pixels arranged in an oblique direction form a single unit cell.

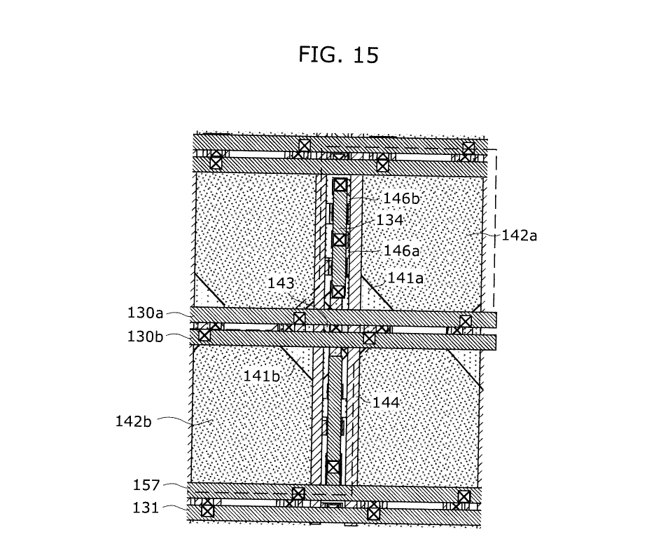

FIGS. 14 and 15 show plan pattern views exemplifying arrangements of elements and layouts of wiring of the unit cell 3 according to Modification 5. It is noted that FIG. 14 illustrates a plan pattern view of the first layer, and FIG. 15 illustrates a plan pattern view of the second layer above the first layer.

Of the amplifying transistors in the unit cell 3, the gates 146a and 146b, the source region 147, and the drain regions 145b and 145c are arranged in a column direction.

The reset transistor 124 is formed of the gate 144, the source region 147c, and the drain region 145a. The source region 147c is electrically connected to the FD region 143 via the contact parts 150b and 150c.

In the unit cell 3 the amplifying transistors 123a and 123b are provided next to the FD region 143 across the gate 141a. This arrangement can provide shorter wiring connecting the FD region 143 and the gates 146a and 146b for the amplifying transistors, which contributes to reducing an increase in parasitic capacitance of the FD and a decrease in voltage conversion gain for the FD.

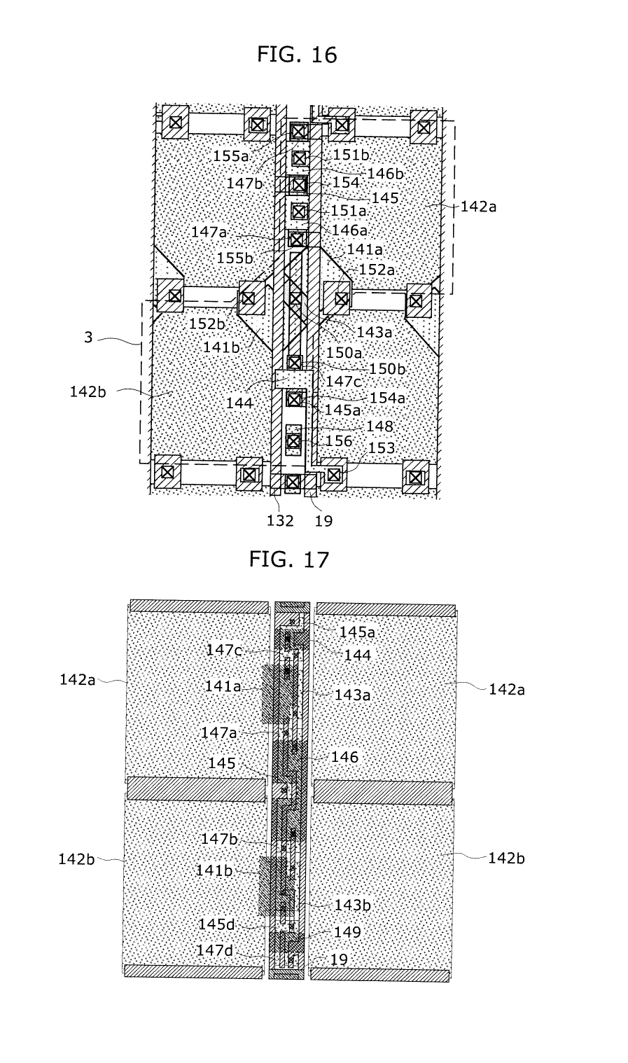

It is noted that, as shown in a plan pattern view of a first layer in FIG. 16, the amplifying transistors in the unit cell 3 may share a drain region. Here, the amplifying transistors in the unit cell 3 are formed of the gates 146a and 146b, the source regions 147a and 147b, and the drain region 145. Here, the source regions 147a and 147b are connected to the column signal line 19 through one of the contact parts 155a and 155b. Here, the contact parts 155a and 155b respectively correspond to the source regions 147a and 147b. The drain region 145 is connected to the power line 132; namely a conductive line, via the contact part 154.

### Modification 6

Here, Modification 6 according to Embodiment 1 shall be described.

In Embodiment 1, the unit cell includes three transistors and does not include a selective transistor. Instead, the unit cell 3 in Modification 6 includes four transistors including a selective transistor.

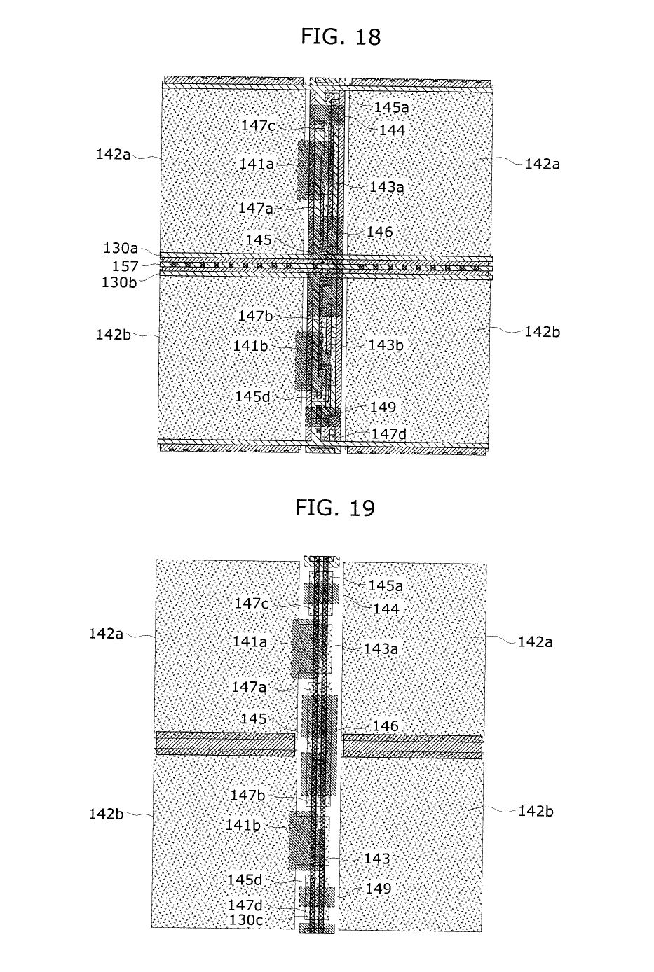

FIGS. 17, 18, and 19 show plan pattern views exemplifying arrangements of elements and layouts of wiring of the unit cell 3 according to Modification 6. It is noted that FIG. 17 illustrates a plan pattern view of the first layer, FIG. 18 illustrates a plan pattern view of the second layer above the first layer, and FIG. 19 illustrates a plan pattern view of the third layer above the second layer.

The FD 125 is formed of the FD regions 143a and 123b. The gate 141a of the transfer transistor 122a is provided between the FD region 143a and the photoelectric converting region 142a of the photoelectric converting element 121a. Similarly, the gate 141b of the transfer transistor 122b is provided between the FD region 143b and the photoelectric converting region 142b of the photoelectric converting element 121b.

The FD region 143a is provided immediately lateral to the photoelectric converting region 142a. The FD region 143b is provided immediately lateral to the photoelectric converting region 142b. When an FD region is provided immediately lateral to a photoelectric converting region, the distance between the FD region and the farthest end of the photoelectric converting region is shorter, compared with the case where the FD region is obliquely provided next to the photoelectric converting region. This feature contributes to developing less residual image. Moreover, this feature makes wiring patterning (lithography process) easier, which contributes to making the manufacturing process easier. Furthermore, the signal charges can be read in the same direction from a photoelectric converting region to an FD region in a single unit cell, which contributes to reducing a characteristic difference between sharing pixels.

The amplifying transistor 123a is formed of the gate 146, the source region 147a, and the drain region 145. Similarly, the amplifying transistor 123b is formed of the gate 146, the source region 147b, and the drain region 145.

The reset transistor 124 is formed of the gate 144, the source region 147c, and the drain region 145a.

The selective transistor is formed of a gate 149, a source region 147d, and a drain region 145d.

### Modification 7

Here, Modification 7 according to Embodiment 1 shall be described.

In Embodiment 1, the unit cell has a cross-section structure shown in FIG. 8. In Modification 7, instead, the unit cell has a waveguide structure which guides incoming light to the photoelectric converting element.

FIG. 20 depicts a cross-sectional view (cross-sectional view taken from line A-A″ in FIG. 6) of the unit cell 3.

Above the photoelectric converting region 142b, the interlayer insulating film 167 has a recess on the surface. Furthermore, on the surface of the interlayer insulating film 167, an antireflection film 170 is formed. This feature makes it possible to provide the waveguide structure for guiding the incoming light to the photoelectric converting region 142b, which contributes to implementing a solid-state imaging device having high sensitivity.

### Modification 8

Here, Modification 8 according to Embodiment 1 shall be described.

In Embodiment 1, the unit cell is a frontside-illuminated cell as shown in FIG. 8. In the unit cell, the incoming light enters the photoelectric converting element at the surface of the substrate on which a signal line is formed. In Modification 8, the unit cell is a backside-illuminated cell. In the backside-illuminated cell, the incoming light enters the photoelectric converting element at the back side of the substrate which is opposite the front side of the substrate. In the backside-illuminated unit cell, light enters the photoelectric converting element at the back side with respect to the region in which the signal line is formed on the substrate. This feature makes it possible for the backside-illuminated unit cell to use the region for forming the conductive line more flexibly than a frontside-illuminated cell.

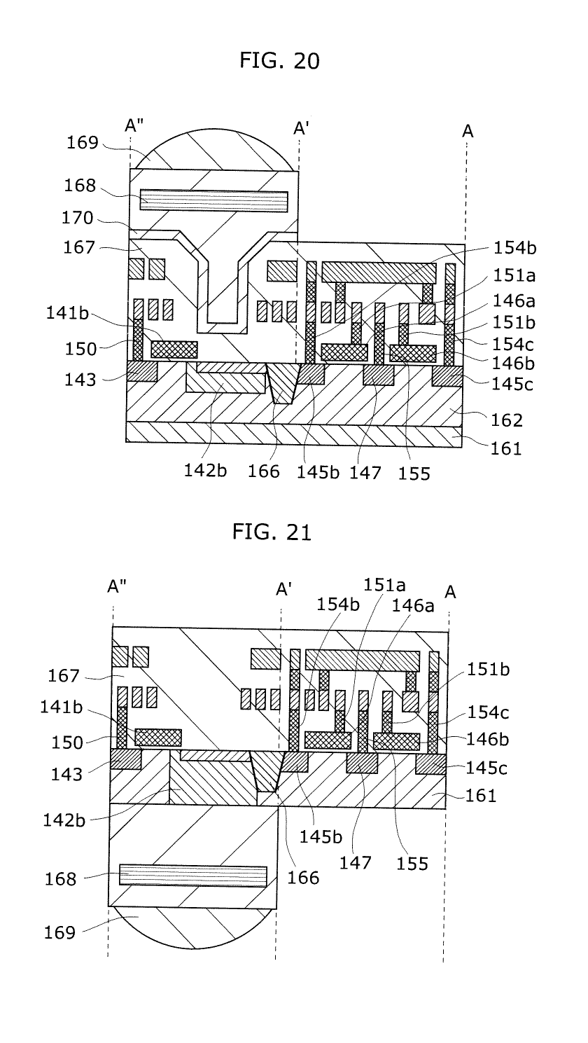

FIG. 21 depicts a cross-sectional view (cross-sectional view taken from line A-A″ in FIG. 6) of the unit cell 3.

The color filter 168 and the micro lens 169 are formed on the backside of an N-type substrate 161. Thanks to the structure, the incoming light passes through the color filter 168 and the micro lens 169, and enters the photoelectric converting region 142b at the backside of the N-type substrate 161.

### Embodiment 2

The unit cell 3 in Embodiment 2 differs from the unit cell 3 in Embodiment 1 in that four pixels are included per unit cell 3 in Embodiment 2 instead of two pixels per in Embodiment 1. Mainly described hereinafter are the differences between Embodiment 2 and Embodiment 1.

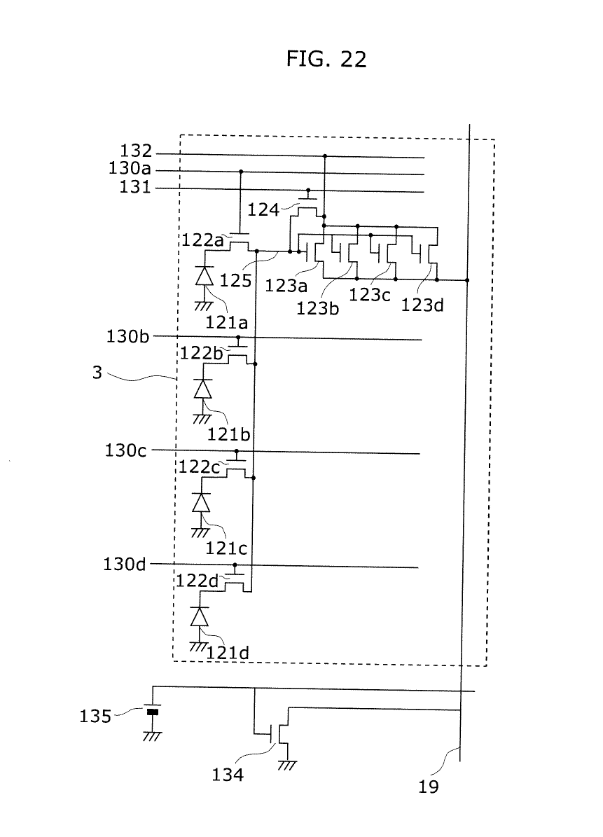

FIG. 22 shows a circuit diagram exemplifying a structure of a unit cell 3.

As circuit elements, each of the unit cells 3 includes, for example, the photoelectric converting elements 121a and 121b, the transfer transistors 122a and 122b, the FD 125, the amplifying transistors 123a and 123b, and the reset transistor 124. Here, each unit cell 3 includes the two photoelectric converting elements 121a and 121b; that is, two pixels. One of the features of the present invention is that the amplifying transistors 123a and 123b are arranged in parallel.

Each unit cell 3 is connected to the column signal line 19, transfer control signal lines 130a, 130b, 130c, and 130d, the reset signal line 131, and the power line 132. The transfer control signal lines 130a, 130b, 130c, and 130d, and the reset signal line 131 are shared with the unit cells 3 arranged in a row direction.

The photoelectric converting elements 121a, 121b, 121c, and 121d have their anodes grounded, and convert incoming light into charges (electrons or holes) depending on an amount of the incoming light, and accumulate the converted charges. The four photoelectric converting elements 121a, 121b, 121c, and 121d are electrically connected in common to the gates of the amplifying transistors 123a, 123b, 123c, and 123d.

Each of the transfer transistors 122a, 122b, 122c, and 122d is provided between (i) the FD 125 and (ii) the photoelectric converting elements 121a, 121b, 121c, and 121d so that the transfer transistors 122a, 122b, 122c, and 122d correspond to the photoelectric converting elements 121a, 121b, 121c, and 121d, respectively. Each of the transfer transistors 122a, 122b, 122c, and 122d transfers, to the FD 125, signal charges generated by one of the respectively corresponding photoelectric converting elements 121a, 121b, 121c, and 121d. Each of the transfer transistors 122a, 122b, 122c, and 122d (i) has the source connected to the cathode of a respectively corresponding one of the photoelectric converting elements 121a, 121b, 121c, and 121d, (ii) has the gate connected to a respectively corresponding one of the transfer control signal lines 130a, 130b, 130c, and 130d, and (iii) has the drain connected to the FD 125 and the gates of the amplifying transistors 123a, 123b, 123c, and the 123d.

One FD 125 is electrically connected in common to the gates of the amplifying transistors 123a, 123b, 123c, and 123d. The FD 125 is also electrically connected in common to the photoelectric converting elements 121a, 121b, 121c, and 121d.

The amplifying transistors 123a, 123b, 123c, and 123d have their gates connected to the FD 125, have their drains connected to the power line 132, and have their sources connected to the column signal line 19. The amplifying transistors 123a, 123b, 123c, and 123d output to the column signal line 19 a signal voltage that corresponds to the amount of the signal charges accumulated in the photoelectric converting elements 121a, 121b, 121c, and 121d. In other words, the amplifying transistors 123a, 123b, 123d, and 123d output a signal voltage corresponding to the potential of one FD 125.

Each of the transfer transistors 122a, 122b, 122c, and 122d, the amplifying transistors 123a, 123b, 123d, and 123d, and the reset transistor 124 is an N-type MOS transistor. It is noted that each of the transfer transistors 122a, 122b, 122c, and 122d, the amplifying transistors 123a, 123b, 123d, and 123d, and the reset transistor 124 may also be a P-type MOS transistor.

In the unit cell 3 shown in FIG. 22, the drains of the transfer transistors 122a, 122b, 122c, and 122d are connected to each other to form a single FD 125. In other words, the photoelectric converting elements 121a, 121b, 121c, and 121d share the FD 125, the reset transistor 124, and the amplifying transistors 123a, 123b, 123c, and 123d.

In the unit cell 3, when the potential of the FD 125 is set to the potential that turns on the amplifying transistors 123a, 123b, 123c, and 123d, the amplifying transistors 123a, 123b, 123c, and 123d, and the constant current transistor 137 form a source follower. Hence, outputted to the column signal line 19 is the potential that dropped from the potential of each of the gates of the amplifying transistors 123a, 123b, 123c, and 123d by a source-gate voltage.

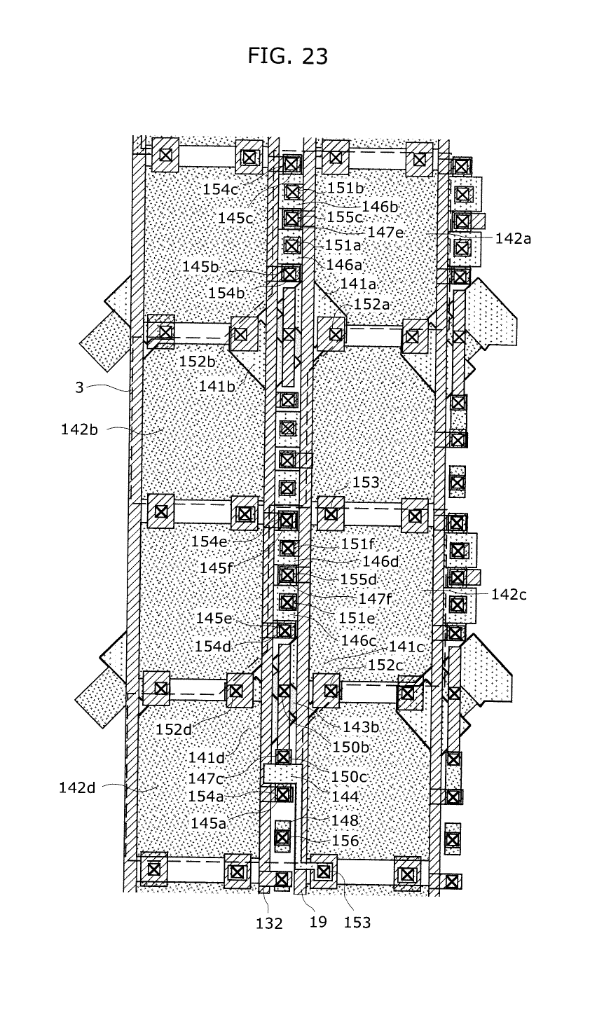

FIG. 23 shows a plan pattern view of a first layer exemplifying an arrangement of elements and a layout of wiring of the unit cell 3 shown in FIG. 22.

The FD 125 is formed of FD regions 143a and 143b. The gate 141a of the transfer transistor 122a is provided between the FD region 143a and the photoelectric converting region 142a of the photoelectric converting element 121a. Similarly, the gate 141b of the transfer transistor 122b is provided between the FD region 143a and the photoelectric converting region 142b of the photoelectric converting element 121b. The gate 141c of the transfer transistor 122c is provided between the FD region 143b and the photoelectric converting region 142c of the photoelectric converting element 121c. The gate 141d of the transfer transistor 122d is provided between the FD region 143b and the photoelectric converting region 142d of the photoelectric converting element 121d.

The FD region 143a is connected to the gates 146a and 146b via a contact part 150a. The FD region 143b is connected to the gates 146c and 146d via a contact part 150b.

The amplifying transistor 123a is formed of the gate 146a, a source region 147e, and the drain region 145b. Similarly, the amplifying transistor 123b is formed of a gate 146b, the source region 147e, and the drain region 145c. Moreover, the amplifying transistor 123c is formed of the gate 146c, a source region 147f, and a drain region 145e. Furthermore, the amplifying transistor 123d is formed of the gate 146d, the source region 147f, and a drain region 145f.

The gate 141a of the transfer transistor 122a is connected to the transfer control signal line 130a via the contact part 152a. Similarly, the gate 141b of the transfer transistor 122b is connected to the transfer control signal line 130b via the contact part 152b. Moreover, the gate 141c of the transfer transistor 122c is connected to the transfer control signal line 130c via a contact part 152c. Furthermore, the gate 141d of the transfer transistor 122d is connected to the transfer control signal line 130d via a contact part 152d.

The reset transistor 124 is formed of the gate 144, the source region 147c, and the drain region 145a. The source region 147c is electrically connected to the FD region 143b via the contact parts 150b and 150c.

The gates 141a, 141b, 141c, 141d, 144, 146a, 146b, 146c, and 146d are made of, for example, polysilicon.

The FD regions 143a and 143b, the source region 147c of the reset transistor 124, and the gates 146a, 146b, 146c, and 146d of the amplifying transistors are connected to one another via the contact parts 150, 151a, 151b, 151e, and 151f.

The drain region 145a of the reset transistor 124 and the drain regions 145b, 145c, 145e, and 145f of the amplifying transistors are connected to the power line 132; namely a conductive line, via the contact parts 154b, 154c, 154d, and 154e.

The source regions 147e and 147f of the amplifying transistors are connected, respectively through the contact parts 155c and 155d, to the column signal line 19.

One well contact region 148 is placed for one unit cell 3. The well contact region 148 is electrically connected to the well voltage supply line 157 via the well contact part 156. Here, the well voltage supply line 157 extends in a column direction and is used for supplying a well voltage; namely a ground level, for example. This structure makes it possible to fix the well voltage.

In the unit cell 3, the amplifying transistors 123a, 123b, 123c, and 123d are arranged so that all the drain regions and the source regions are arranged in a line. This arrangement contributes to reducing the arrangement area for the amplifying transistors 123a, 123b, 123c, and 123d.

In the unit cell 3, the amplifying transistors 123a and 123b share the source region 147e and the amplifying transistors 123c and 123d share the source region 147f. This arrangement makes it possible to secure a larger area for the amplifying transistors 123a, 123b, 123c, and 123d. This feature makes it possible to increase the sizes of the gate widths W for the amplifying transistors 123a, 123b, 123c, and 123d, which contributes to reducing random noise.

As shown in FIG. 16 of the unit cell 3 according to Embodiment 2, a drain region may be shared between the amplifying transistors 123a and 123b, and another drain region may be shared between the amplifying transistors 123c and 123d.

In the unit cell 3, the sizes of the gate width W and the gate length L are the same for the amplifying transistors 123a, 123b, 123c, and 123d. This feature contributes to reducing variation in the threshold voltage Vth caused by the variation in the sizes of the amplifying transistors 123a, 123b, 123c, and 123d. Here, when Vin is an input to a source follower circuit, Vout is an output of the source follower circuit, α is a gain (approximately 0.9 times) of the source follower circuit, Vout=α (Vin−Vth) is held. Reduction of the variation in the threshold voltage Vth can reduce the voltage variation in the voltage Vout outputted to the column signal line 19. This feature contributes to securing a dynamic range and to reducing variation in the dynamic range for the source follower circuit.

In the unit cell 3, the channels of the amplifying transistors 123a, 123b, 123c, and 123d are embedded channels. Consequently, the voltage signals become insusceptible to crystal defects between an oxide film and a silicon interface, which contributes to reducing the RTS noise which is a kind of 1/f noise.

In the unit cell 3, the four amplifying transistors 123a, 123b, 123c, and 123d are arranged in parallel. Hence, the random noise developed in the unit cell 3 and caused by a constant current source can be reduced to 1/√4.

In the unit cell 3, the gate 146a of the amplifying transistor 123a and the gate 146b of the amplifying transistor 123b are electrically connected to each other with a signal line which is a metal line. Similarly, the gate 146c of the amplifying transistor 123c and the gate 146d of the amplifying transistor 123d are electrically connected to each other with a signal line which is a metal line. This feature makes it possible to reduce the length of the gates 146a, 146b, 146c, and 146d in a column direction, which contributes to increasing the gate widths W for the amplifying transistors. The layout around the contact parts 155c and 155d successfully avoids arranging gates side by side. This feature contributes to securing the room for the contact parts 155c and 155d.

In the unit cell 3, the amplifying transistors 123a and 123b are respectively placed next to the gates 141a and 141b of the transfer transistors 122a and 122b via the drain region 145b of the amplifying transistor 123a. Such a feature makes it possible to electrically separate, via a diffusion region connected to a power line, (i) a diffusion region (channel region) below the gates 146a and 146b that adjust the threshold voltage Vth for the amplifying transistors 123a and 123b from (ii) a region channel below the gates 141a and 141b of the transfer transistors 122a and 122b. This feature makes it possible to adjust the threshold voltage Vth for the amplifying transistors 123a and the 123b without affecting the characteristics in reading the signal charges by the transfer transistors 122a and 122b from the pixels. For example, thermal noise is represented as Vn̂2=8k×T/(3 gm), gm =(μ×Cox) W/L×(Vgs−Vth). Here, as the threshold voltage Vth is made lower, gm can be made higher and the thermal noise can be reduced.

In the unit cell 3, the amplifying transistors 123a, 123b, 123c, and 123d are provided so that the gate areas of the amplifying transistors are successfully increased. This feature makes it possible to give the amplifying transistors a more flexible layout and process (manufacturing) condition without affecting the read characteristics of the pixels.

In the unit cell 3 the amplifying transistors 123a and 123b are provided next to the FD region 143 across the gate 141a. This arrangement can provide shorter wiring connecting the FD region 143a and the gates 146a and 146b for the amplifying transistors. This feature contributes to reducing an increase in parasitic capacitance of the FD and a decrease in voltage conversion gain for the FD.

As described above, in the solid-state imaging device 100 according to Embodiment 2, one unit cell 3 has the amplifying transistors 123a, 123b, 123c, and 123d arranged in parallel in order to reduce noise. This feature contributes to implementing a solid-state imaging device which develops low noise.

Furthermore, the solid-state imaging device 100 in Embodiment 2 also has the same features as that in Embodiment 1 have. Hence, the present invention can achieve all of the sensitivity characteristics, the spectral characteristics, and the low noise performance of the solid-state imaging device in a high level.

### Modification 9

Here, Modification 9 according to Embodiment 2 shall be described.

In Embodiment 2, one unit cell includes four pixels arranged in an oblique direction. In Modification 9, instead, one unit cell includes pixels arranged next to each other in a column or horizontal direction.

Furthermore, in Embodiment 2, one unit cell includes four amplifying transistors arranged in parallel. In Modification 9, instead, one unit cell includes two amplifying transistors arranged in parallel.

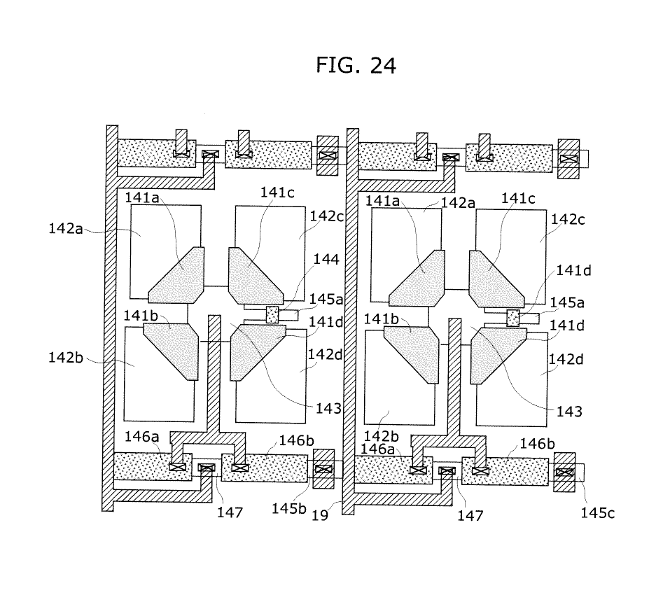

FIG. 24 shows a plan pattern view of a first layer exemplifying an arrangement of elements and a layout of wiring of the unit cell 3 according to Modification 9.

The FD 125 is formed of the FD region 143. The gate 141a of the transfer transistor 122a is provided between the FD region 143 and the photoelectric converting region 142a of the photoelectric converting element 121a. Similarly, the gate 141b of the transfer transistor 122b is provided between the FD region 143 and the photoelectric converting region 142b of the photoelectric converting element 121b. The gate 141c of the transfer transistor 122c is provided between the FD region 143 and the photoelectric converting region 142c of the photoelectric converting element 121c. The gate 141d of the transfer transistor 122d is provided between the FD region 143 and the photoelectric converting region 142d of the photoelectric converting element 121d.

The amplifying transistor 123a is formed of the gate 146a, the source region 147, and the drain region 145b. Similarly, the amplifying transistor 123b is formed of the gate 146b, the source region 147, and the drain region 145c.

The reset transistor 124 is formed of the gate 144, the FD region 143, and the drain region 145a.

The source region 147 for amplifying transistors is connected to the column signal line 19.

In the unit cell 3, the amplifying transistors 123a and 123b are arranged so that all the drain regions and the source regions are arranged in a line. This arrangement contributes to reducing the arrangement area for the amplifying transistors 123a and 123b.

In the unit cell 3, the amplifying transistors 123a and 123b share the source region 147, which contributes to securing a larger area for the amplifying transistors 123a, 123b, 123c, and 123d. This feature makes it possible to increase the sizes of the gate widths W for the amplifying transistors 123a and 123b, which contributes to reducing random noise.

In the unit cell 3, the two amplifying transistors 123a and 123b are arranged in parallel. Hence, the random noise developed in the unit cell 3 and caused by a constant current source can be reduced to 1/√2.

### Modification 10

Here, Modification 10 according to Embodiment 2 shall be described.

In Embodiment 2, one unit cell includes four pixels arranged in an oblique direction. In Modification 10, instead, one unit cell includes four pixels arranged next to each other in a column direction.

Furthermore, in Embodiment 2, one unit cell includes four amplifying transistors arranged in parallel. In Modification 10, instead, one unit cell includes two amplifying transistors arranged in parallel.

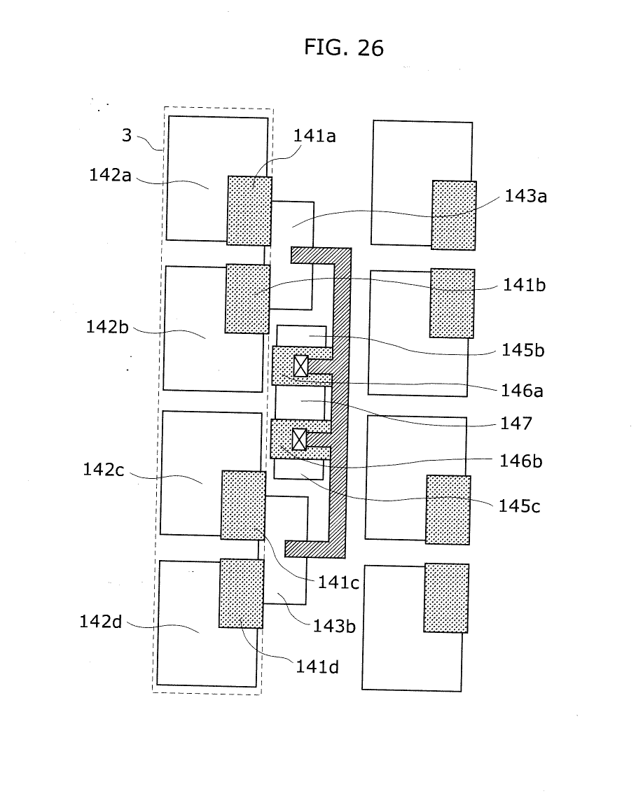

FIG. 26 shows a plan pattern view of a first layer exemplifying an arrangement of elements and a layout of wiring of the unit cell 3 according to Modification 10.

The FD 125 is formed of the FD regions 143a and 143b. The gate 141a of the transfer transistor 122a is provided between the FD region 143a and the photoelectric converting region 142a of the photoelectric converting element 121a. Similarly, the gate 141b of the transfer transistor 122b is provided between the FD region 143a and the photoelectric converting region 142b of the photoelectric converting element 121b. The gate 141c of the transfer transistor 122c is provided between the FD region 143b and the photoelectric converting region 142c of the photoelectric converting element 121c. The gate 141d of the transfer transistor 122d is provided between the FD region 143b and the photoelectric converting region 142d of the photoelectric converting element 121d.

The amplifying transistor 123a is formed of the gate 146a, the source region 147, and the drain region 145b. Similarly, the amplifying transistor 123b is formed of the gate 146b, the source region 147, and the drain region 145c.

In the unit cell 3, the amplifying transistors 123a and 123b are arranged so that all the drain regions and the source regions are arranged in a line. This arrangement contributes to reducing the arrangement area for the amplifying transistors 123a and 123b.

In the unit cell 3, the amplifying transistors 123a and 123b share the source region 147, which contributes to securing a larger area for the amplifying transistors 123a, 123b, 123c, and 123d. This feature makes it possible to increase the sizes of the gate widths W for the amplifying transistors 123a and 123b, which contributes to reducing random noise.

In the unit cell 3, the two amplifying transistors 123a and 123b are arranged in parallel. Hence, the random noise developed in the unit cell 3 and caused by a constant current source can be reduced to 1/√2.

Although only some exemplary embodiments of a solid-state imaging device according to the present invention have been described in detail above, those skilled in the art will readily appreciate that many modifications are possible in the exemplary embodiments without materially departing from the novel teachings and advantages of the present invention. Accordingly, all such modifications are intended to be included within the scope of the present invention.

In the embodiments, for example, the AD converting circuit 25 may be provided outside the solid-state imaging device 100.

In the embodiments, the unit cell 3 has two-layer wiring structure; instead, the unit cell 3 may have a three-or-more-layer wiring structure. In such a case, the power line 132 may be reinforced. Moreover, the structure can decrease thermal resistance of the power line 132, which contributes to reducing noise from the power line. For example, in the wiring, a contact is disposed to the power line 132 in the second layer, and the power line 132 is arranged in a reticular pattern so that the power line 132 is open with the photoelectric converting regions 142a and 142b. This structure successfully reduces the resistance of the power line 132 with respect to vertical and horizontal directions.

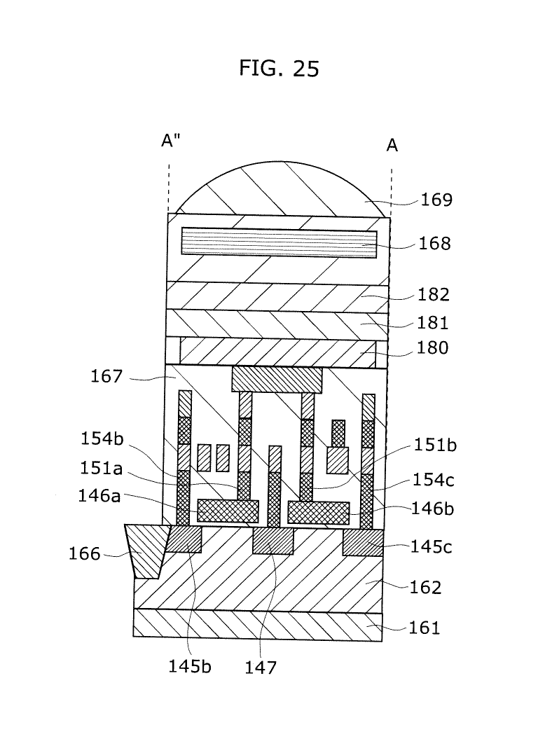

Moreover, in the embodiments, the solid-state imaging device may be a multi-layer image sensor. Here, in the unit cell 3 shown in the cross-sectional view illustrated in FIG. 25, a pixel electrode 180, an organic photoelectric converting film 181, a counter electrode 182, the color filter 168, and the micro lens 169 are stacked on the interlayer insulating film 167.

Moreover, in the embodiments, the unit cell 3 includes a transfer transistor; instead, the unit cell 3 does not have to include a transfer transistor. In such a case, for example, a contact may be provided on the photoelectric converting region 142a, and the contact may be connected to a contact part 151a of the gate 146a for an amplifying transistor.

### INDUSTRIAL APPLICABILITY

The present invention is used for a solid-state imaging device, such as a digital camera.

What is claimed is:

1. A solid-state imaging device comprising
unit cells which are arranged in two dimensions and each of which includes:
a photoelectric converting element which photoelectrically converts incident light; and
amplifying transistors each of which has a gate that receives a voltage according to signal charges accumulated in the photoelectric converting element.

2. The solid-state imaging device according to claim 1,
wherein the unit cell includes photoelectric converting elements including the photoelectric converting element, and
the photoelectric converting elements share the amplifying transistors.

3. The solid-state imaging device according to claim 1,
wherein the unit cell includes a transfer transistor which is provided between (i) the photoelectric converting element and (ii) gates of the amplifying transistors.

4. The solid-state imaging device according to claim 1,
wherein the amplifying transistors share one of a source region and a drain region.

5. The solid-state imaging device according to claim 4,
wherein, with respect to the shared one of the source region and the drain region for the amplifying transistors, a direction of a current flow between the source region and the drain region of one of the amplifying transistors and a direction of a current flow between the source region and the drain region of another one of the amplifying transistors are symmetrical.

6. The solid-state imaging device according to claim 1,
wherein, in each of the unit cells that are neighboring with each other, the amplifying transistors share one of a source region and a drain region.

7. The solid-state imaging device according to claim 1,
wherein the unit cell includes a reset transistor which resets a potential of the gate of each of the amplifying transistors.

8. The solid-state imaging device according to claim 1,
wherein all of drain regions and source regions for the amplifying transistors are arranged in a line.

9. The solid-state imaging device according to claim 1,
wherein the gates of the amplifying transistors are same in width.

10. The solid-state imaging device according to claim 1,
wherein the gates of the amplifying transistors are same in length.

11. The solid-state imaging device according to claim 1,
wherein the amplifying transistors share a gate.

12. The solid-state imaging device according to claim 1,
wherein the gates of the amplifying transistors are connected to each other via a signal line.

13. The solid-state imaging device according to claim 1, further comprising
a signal line which is connected to the unit cells and transmits a signal voltage outputted from the unit cells,
wherein source regions of the amplifying transistors are connected to the signal line.

14. A camera comprising:
a first chip on which a solid-state imaging device is formed, the solid-state imaging device including (i) unit cells arranged in two dimensions, and (ii) an AD conversion circuit which converts voltage signals, outputted from the unit cells, into digital signals; and
a second chip on which a digital signal processing circuit is formed, the digital signal processing circuit processing the digital signals outputted from the first chip,
wherein each of the unit cells includes:
a photoelectric converting element which photoelectrically converts incident light;
a transfer transistor which reads signal charges accumulated in the photoelectric converting element; and
amplifying transistors each of which has a gate that receives a voltage according to signal charges accumulated in the photoelectric converting element.
